(19) United States
(12) Patent Application Publication
(10) Pub. No.: US 2011/0142089 A1
(43) Pub. Date: Jun. 16, 2011

(54) SEMICONDUCTOR LASER DEVICE AND METHOD OF MANUFACTURING THE DEVICE

(76) Inventor: Akiyoshi KUDO, Hyogo (JP)

(21) Appl. No.: 12/917,211

(22) Filed: Nov. 1, 2010

(30) Foreign Application Priority Data
Dec. 11, 2009 (JP) 2009-282006

(51) Int. Cl. H01S 5/22; H01S 5/323; H01L 21/306

(52) U.S. Cl. 372/46.012; 438/39; 257/E21.22

(57) ABSTRACT

A first semiconductor layer, an active layer, a second semiconductor layer, and a contact layer are sequentially stacked on a substrate. A ridge portion extending between both facets of a resonator is provided in the second semiconductor layer and the contact layer. A current confining layer is formed to be in contact with the ridge portion. The current confining layer has an opening on an upper surface of the ridge portion. A first electrode in contact with the contact layer is formed in the opening. A second electrode is provided on the first electrode. A non-current injection portion in contact with the contact layer is provided on the upper surface of the ridge portion near the resonator facet. The current confining layer and the non-current injection portion are formed of the same dielectric film. The second electrode is spaced apart from an upper surface region of the non-current injection portion.

### CROSS-REFERENCE TO RELATED APPLICATION

This application claims priority to Japanese Patent Application No. 2009-282006 filed on Dec. 11, 2009, the disclosure of which including the specification, the drawings, and the claims is hereby incorporated by reference in its entirety.

### BACKGROUND

The present disclosure relates to semiconductor laser devices and methods of manufacturing the devices; and more particularly to semiconductor laser devices having electrode structures utilizing a junction interface between metal and compound semiconductor, which has a different work function from the metal, and methods of manufacturing the devices.

Source/drain electrodes of a high electron mobility field effect transistor (HEMT) utilizing gallium arsenide (GaAs), which is representative of a compound semiconductor material with a narrow bandgap, exhibit ohmic properties by forming a eutectic alloy of metal and a heavily doped GaAs semiconductor layer. On the other hand, a gate electrode is configured by utilizing a Schottky contact interface between metal and semiconductor. In recent years, power devices utilizing wide-bandgap materials such as gallium nitride (GaN) and silicon carbide (SiC), which have been intensively researched for practical use, all of source/drain electrodes and a gate electrode have electrode structures utilizing Schottky contact interfaces.

A semiconductor light-emitting device utilizing gallium nitride (GaN) will be described below as an example. In an electrode structure of a laser diode (LD), which has rapidly spread as a key device for optical pickup in a high-density optical disk system, and in an electrode structure of a light-emitting diode (LED), which has been put to wide practical use as a illumination light source of an energy saving solid state device in place of conventional illumination sources, contact is obtained by Schottky-connecting metal to a GaN semiconductor layer, as in a gate electrode of a HEMT utilizing GaAs.

A GaN semiconductor laser diode (LD) is a Fabry-Perot laser, in which injected carriers are confined within a quantum well active layer by a p-n double heterostructure. The carriers are injected into the active layer through a contact layer from a Schottky electrode formed on a ridge waveguide structure provided in an upper cladding layer. The ridge waveguide structure limits injected currents, thereby limiting the width of a resonance region for laser oscillation in the active layer. This stabilizes a transverse mode to reduce the operating current. For high-output power operation, a non-current injection region is formed near facets of a ridge waveguide to effectively reduce catastrophic optical damages (CODs) of resonator facets, thereby increasing life expectancy of the device.

As such, in a GaN semiconductor laser diode (LD), establishment of technique of effectively reducing the CODs of resonator facets is required. Also, in order to reduce power consumption and to increase life expectancy, establishment of electrode technique of injecting carriers into an active layer with high efficiency to reduce the operating current by connecting a metal electrode, which is a Schottky electrode formed on a semiconductor surface of a ridge resonator, to the semiconductor surface with stability and low resistance.

FIG. 22A is a cross-sectional view taken in a width direction (i.e., the direction perpendicular to an extending direction of a ridge) in a central portion of a resonator of a semiconductor laser device according to a first conventional art shown in Japanese Patent Publication No. 2008-034587. FIG. 22B is a cross-sectional view taken in the width direction near resonator facets in the semiconductor laser device according to the first conventional art. FIG. 22C is a cross-sectional view taken in a length direction (i.e., the extending direction of the ridge) in the semiconductor laser device according to the first conventional art.

As shown in FIGS. 22A-22C, a GaN semiconductor layer 102 including a ridge stripe 105 is formed on an n-type GaN substrate 101. A p-side electrode including a Pd film 103 and a Pt film 104 is formed on the ridge stripe 105 other than the vicinity of the resonator facets. An insulating film 106 is formed to cover the upper surface of the GaN semiconductor layer 102 other than the ridge stripe 105, the upper surface of the ridge stripe 105 near the resonator facets, both side surfaces of the ridge stripe 105, and both side surfaces of the p-side electrode. An isolation electrode 107 is formed on the insulating film 106 to be in contact with the upper surface of the p-side electrode. A pad electrode 108 is formed on the isolation electrode 107 other than the vicinity of the resonator facets. An n-side electrode 109 is formed on the lower surface of the n-type GaN substrate 101.

That is, Japanese Patent Publication No. 2008-034587 shows a conventional technique which reduces CODs due to optical damages in a non-current injection region of the resonator facets and near the resonator facets to increase output power and life expectancy of a semiconductor laser diode. Furthermore, according to the technique shown in Japanese Patent Publication No. 2008-034587, a dielectric film (i.e., the insulating film 106) defining the non-current injection region is formed on the p⁺-type GaN contact layer (a vertex of the ridge stripe 105) at the side of the resonator facets. Thus, an ohmic p-electrode (i.e., the p-side electrode including the Pd film 103 and the Pt film 104) has facets being in contact with the dielectric film and located on the inner side of the resonator facets. Also, a main p-electrode (i.e., the isolation electrode 107) is formed to cover the dielectric film and the ohmic p-side electrode.

FIG. 23A is a cross-sectional view taken in a length direction near a resonator facet of a semiconductor laser device according to a second conventional art shown in Japanese Patent Publication No. 2008-227002. FIG. 23B is a bottom view near the resonator facet of the semiconductor laser device according to the second conventional art.

As shown in FIGS. 23A and 23B, a first nitride semiconductor layer 202, an active layer 203, a second nitride semiconductor layer 204, and a ridge 205 are sequentially formed on a substrate 201. A p-electrode 206 is formed on the ridge 205 other than the vicinity of a resonator facet 208. An n-electrode 207 is formed on the lower surface of the substrate 201 other than the vicinity of the resonator facet 208. A protective film 209a covering the resonator facet 208, a protective film 209b covering the lower surface of the substrate 201 and the upper surface of the ridge 205 near the resonator facet 208, and a protective film 209c covering ends of the p-electrode 206 and the n-electrode 207 are provided.

That is, in a semiconductor laser element made of a nitride semiconductor material shown in Japanese Patent Publication No. 2008-227002, a facet of the p-electrode 206 is located behind near the resonator surface to avoid problems during a manufacturing process of the element. This prevents removal of an electrode due to impact of cleavage when forming the resonator facet, and improves adhesiveness of the protective films at the side of the resonator facet.

### SUMMARY

A native oxide layer made of Ga, N, and O and having a thickness of less than about 1 nm exists on a surface of a p⁺-type GaN layer at a vertex of a ridge resonator, on which a p-electrode (Schottky electrode) made of high work function metal such as Pd, Pt or Ni is formed. Contact characteristics at the connection interface between the p-electrode and the p⁺-type GaN layer depend on the Fermi level determined by the native oxide layer which is continuous from the semiconductor crystal surface of the region, to which the p-electrode is connected, to the semiconductor crystal surface of the non-current injection region. Thus, the electrode structure needs to be designed in view of not only the p⁺-type GaN layer of the current injection region at the vertex of the ridge resonator but also the p⁻-type GaN layer of the non-current injection region, which has a continuous surface with the p⁺-type GaN layer of the current injection region.

However, in the structure shown in Japanese Patent Publication No. 2008-034587, the main p-electrode covers the ohmic p-electrode, and the dielectric film of the non-current injection region as well. Thus, a change in the Fermi level determined by the interface between the p⁺-type GaN contact layer and the dielectric film of the non-current injection region, which is continuous with the crystal surface of the p⁺-type GaN contact layer in the region to which the ohmic p-electrode is connected, affects the Fermi level at the interface between the ohmic p-electrode and the p⁺-type GaN contact layer, thereby degrading the contact characteristics.

On the other hand, in the structure shown in Japanese Patent Publication No. 2008-227002, the above problem does not occur. However, the dielectric film material used for a facet coating film also coats the non-current injection region when coating the facet. Thus, in accordance with a change in stress characteristics of the dielectric film material, a change in optical characteristics such as a refractive index of the material, or a stoichiometric change of the material; a change in conductivity characteristics on the laser-emitting facet and the like may occur. Therefore, the structure in which the material of the facet coating film is also used as a dielectric film of the non-current injection region is problematic, since the structure impairs the function of the dielectric film of the non-current injection region, which is originally required.

In view of the foregoing, it is an objective of the present disclosure to provide a semiconductor laser device achieving high output power, long life, and a low operation voltage.

The present inventor has found that the following technical means is required to achieve the above-described objective. Specifically, contact resistance between an ohmic p-electrode and a p⁺-type GaN contact layer need to be reduced by eliminating the influence of a change in the Fermi level at the crystal surface of the p⁺-type GaN contact layer of a non-current injection region, which is continuous with the crystal surface of the p⁺-type GaN contact layer of the region to which the ohmic p-electrode is connected (i.e., the connection interface between the dielectric film of the non-current injection region and the p⁺-type GaN contact layer), on the Fermi level at the interface between the ohmic p-electrode and the p⁺-type GaN contact layer. In order to eliminate the influence, it is necessary to reduce a change of state of the native oxide layer existing on the surface of the p⁺-type GaN contact layer which is located near the resonator facet of the semiconductor laser device and is continuous with the surface of the p⁻-type GaN contact layer of the current injection region (i.e., the surface of the p⁺-type GaN contact layer in the region in which the dielectric film used for the non-current injection region is in contact with the p⁺-type GaN contact layer). This reduces problems that the change in the state of the native oxide layer affects the Fermi level at the interface between the ohmic p-electrode and the p⁺-type GaN contact layer.

The present disclosure was made based on the above findings.

A semiconductor laser device according to the present disclosure includes a substrate; a first conductivity type semiconductor layer, an active layer, a second conductivity type semiconductor layer, and a second conductivity type contact layer, which are sequentially stacked on the substrate; a ridge portion provided in the second conductivity type semiconductor layer and the second conductivity type contact layer, and extending between both facets of a resonator; a current confining layer being in contact with the ridge portion, and having an opening on an upper surface of the ridge portion; a first electrode provided in the opening to be in contact with the second conductivity type contact layer; and a second electrode provided on the first electrode. A non-current injection portion is provided on the upper surface of the ridge portion near the resonator facets to be in contact with the second conductivity type contact layer. The current confining layer and the non-current injection portion are formed of a same dielectric film. The second electrode is spaced apart from an upper surface region of the non-current injection portion.

According to the semiconductor laser device of the present disclosure, the second electrode, which is electrically conductive with (i.e., having the same potential as) the first electrode, is not provided on the dielectric film serving as the non-current injection portion near the resonator facet. Thus, characteristics of the connection interface between the first electrode and the second conductivity type contact layer are not affected by the Fermi level determined by the native oxide layer formed on the crystal surface of the second conductivity type contact layer under the non-current injection portion which is continuous with the crystal surface of the second conductivity type contact layer under the first electrode. Therefore, contact resistance between the first electrode and the second conductivity type contact layer is stable, thereby providing a semiconductor laser device achieving high output power, long life, and low operation voltage.

In the semiconductor laser device according to the present disclosure, the first electrode may be in contact with a sidewall surface of the non-current injection portion.

In the semiconductor laser device according to the present disclosure, the second electrode may extend to a side of the ridge portion to be in contact with the dielectric film in a region other than regions near the resonator facets provided with the non-current injection portion.

In the semiconductor laser device according to the present disclosure, a native oxide layer may be formed on a surface of a part of the second conductivity type contact layer which is in contact with the first electrode. In this case, the native oxide layer may contain elements constituting the second conductivity type contact layer and oxygen. The native oxide layer may have a thickness larger than 0 nm and less than 1 nm.

In the semiconductor laser device according to the present disclosure, a semiconductor multilayer including the first conductivity type semiconductor layer, the active layer, the second conductivity type semiconductor layer, and the second conductivity type contact layer may be made of group III-V nitride compound semiconductor represented by InₓAl_{y}Ga_{1-x-y}N (where 0≦x≦1, 0≦y≦1, and x+y≦1). With this configuration, the oscillation wavelength of the semiconductor laser device may range from blue violet to green.

In the semiconductor laser device according to the present disclosure, a part of the first electrode being in contact with the upper surface of the second conductivity type contact layer may be made of a single metal or plural metals selected from the group consisting of Pd, Pt, and Ni. With this configuration, a p-electrode, which can be connected with low contact resistance to the p⁺-type GaN contact layer made of e.g., group III-V nitride compound semiconductor with a wide bandgap, can be formed as a first electrode.

In the semiconductor laser device according to the present disclosure, the dielectric film may be a silicon oxide film. This stabilizes the voltage of the laser to improve the COD level, and improves linearity of current-optical output power (IL) characteristics, thereby mitigating an increase in the operating current according to an increase in the threshold current to enable high-output power operation. Therefore, a semiconductor laser device, which can stably monitor and control optical output power when used in e.g., an optical disk, can be provided.

In the semiconductor laser device according to the present disclosure, a distance between an end of the first electrode and one of the resonator facets may range from 1 μm to 10 μm. This stabilizes the voltage of the laser to improve the COD level, and improves the linearity of IL characteristics, thereby mitigating an increase in the operating current current-optical output power according to an increase in the threshold current to enable high-output power operation. Therefore, a semiconductor laser device, which can stably monitor and control optical output power when used in e.g., an optical disk, can be provided.

A manufacturing method of a semiconductor laser device according to the present disclosure includes the steps of: (a) forming a semiconductor multilayer, in which a first conductivity type semiconductor layer, an active layer, a second conductivity type semiconductor layer, and a second conductivity type contact layer are sequentially stacked on a substrate; (b) forming a ridge portion extending between both facets of a resonator by etching the second conductivity type semiconductor layer and the second conductivity type contact layer; (c) forming a dielectric film on the semiconductor multilayer; (d) after applying first resist onto the dielectric film, deactivating the first resist; (e) exposing a part of the dielectric film located on the ridge portion by etching back the first resist; (f) after applying second resist onto the first resist, performing exposure and development of the second resist, thereby forming an opening in an electrode formation region on the ridge portion; (g) removing a part of the dielectric film located in the electrode formation region by etching using the first resist and the second resist as a mask to expose the upper surface of the ridge portion in the electrode formation region; (h) forming a first electrode film on the exposed portion of the upper surface of the ridge portion, the first resist, and the second resist; and (i) lifting off the first resist and the second resist to remove the first electrode film formed on the first resist and the second resist, thereby forming a first electrode on the upper surface of the ridge portion.

According to the manufacturing method of the semiconductor laser device of the present disclosure, the semiconductor laser device according to the present disclosure, e.g., a GaN semiconductor laser diode (LD), having the above-described features and advantages can be manufactured. Specifically, a change of state of the native oxide layer formed at the connection interface between the upper surface of the ridge portion made of semiconductor and the first electrode is reducible. This controls the Fermi level at the connection interface to stabilize the voltage of the laser, thereby improving the COD level. Therefore, a semiconductor laser device achieving high output power and long life characteristics can be obtained.

Note that, in the manufacturing method of the semiconductor laser device according to the present disclosure, the non-current injection portion defining the non-current injection region, and the current confining layer provided along the extending direction of the ridge portion and having an opening on the upper surface of the ridge portion are formed of a monolithic-integrated dielectric film.

In the manufacturing method of the semiconductor laser device according to the present disclosure, before the step (d), a part of the dielectric film may be etched by dry etching with inert gas. In this case, the inert gas may be argon.

In the manufacturing method of the semiconductor laser device according to the present disclosure, in the step (g), wet etching may be used for etching the dielectric film. In this case, in the step (g), solution containing hydrofluoric acid may be used for etching the dielectric film.

In the manufacturing method of the semiconductor laser device according to the present disclosure, in the step (i), the first resist and the second resist may be lifted off with cleaning agent containing a nitrogen compound. In this case, the cleaning agent containing the nitrogen compound may be cleaning agent containing pyrrolidone.

The manufacturing method of the semiconductor laser device according to the present disclosure may further include after the step (i), the step (j) forming a second electrode on the first electrode. In this case, the second electrode may include a plurality of metal layers, and at least one of the plurality of metal layers may be formed by plating. Furthermore, the at least one metal layer formed by the plating may have a thickness of 1 μm or more. As such, the second electrode, which is smoothly connected to the first electrode even at the step portion, can be formed.

In the manufacturing method of the semiconductor laser device according to the present disclosure, the semiconductor multilayer may be made of group III-V nitride compound semiconductor represented by InₓAl_{y}Ga_{1-x-y}N (where 0≦x≦1, 0≦y≦1, and x+y≦1). With this configuration, the oscillation wavelength of the semiconductor laser device may range from blue violet to green.

As described above, according to the present disclosure, for example, in a GaN semiconductor laser diode made of a wide-bandgap material, a p-electrode connected to a contact layer with low contact resistance can be provided. Therefore, a semiconductor laser device achieving high output power, long life, and low operation voltage can be provided. Furthermore, by using group nitride compound semiconductor represented by e.g., InₓAl_{y}Ga_{1-x-y}N (where 0≦x≦1, 0≦y≦1, and x+y≦1), a ridge type laser with an oscillation wavelength ranging from blue violet to green can be realized.

Moreover, according to the present disclosure, the non-current injection portion defining the non-current injection region, and the current confining layer are formed of the monolithic-integrated dielectric film. Therefore, the device can be protected so that physicochemical influence due to the wafer process and the cleavage/coating film formation process does not affect the native oxide layer on the surface of the semiconductor layer which is the upper surface of a ridge waveguide structure.

Furthermore, since the Fermi level at the connection interface between the upper surface of the ridge portion made of semiconductor and the first electrode can be stabilized, low voltage characteristics and the COD level can be improved and an increase in the operating current according to an increase in the threshold current can be mitigated. That is, a ridge type laser enabling low current oscillation and high output power can be realized.

That is, in the present disclosure, by providing a p-electrode operatable at a low voltage, a semiconductor laser device such as a ridge type laser enabling low current oscillation and high output power. Furthermore, the present disclosure is excellent in the COD level, linearity of current-optical output power (IL) characteristics, high-output power operation, and the like, and is particularly useful for applying as a laser light source for optical pickup for example, in a high-density optical disk system.

### BRIEF DESCRIPTION OF THE DRAWINGS

FIG. 1 is a top view illustrating the structure of a semiconductor laser device according to an embodiment.

FIG. 2A is a cross-sectional view taken along the line A-A′ (a non-current injection region) of FIG. 1. FIG. 2B is a cross-sectional view taken along the line B-B′ (a current injection region) of FIG. 1. FIG. 2C is a cross-sectional view taken along the line C-C′ (in the extending direction of a ridge) of FIG. 1.

FIGS. 3A-3C are cross-sectional views illustrating a manufacturing step of the semiconductor laser device according to the embodiment. FIG. 3A is a cross-sectional view illustrating a manufacturing step taken along the line A-A′ (the non-current injection region) of FIG. 1. FIG. 3B is a cross-sectional view illustrating a manufacturing step taken along the line B-B′ (the current injection region) of FIG. 1. FIG. 3C is a cross-sectional view illustrating a manufacturing step taken along the line C-C′ (in the extending direction of the ridge) of FIG. 1.

FIGS. 4A-4C are cross-sectional views illustrating a manufacturing step of the semiconductor laser device according to the embodiment. FIG. 4A is a cross-sectional view illustrating a manufacturing step taken along the line A-A′ (the non-current injection region) of FIG. 1. FIG. 4B is a cross-sectional view illustrating a manufacturing step taken along the line B-B′ (the current injection region) of FIG. 1. FIG. 4C is a cross-sectional view illustrating a manufacturing step taken along the line C-C′ (in the extending direction of the ridge) of FIG. 1.

FIGS. 5A-5C are cross-sectional views illustrating a manufacturing step of the semiconductor laser device according to the embodiment. FIG. 5A is a cross-sectional view illustrating a manufacturing step taken along the line A-A′ (the non-current injection region) of FIG. 1. FIG. 5B is a cross-sectional view illustrating a manufacturing step taken along the line B-B′ (the current injection region) of FIG. 1. FIG. 5C is a cross-sectional view illustrating a manufacturing step taken along the line C-C′ (in the extending direction of the ridge) of FIG. 1.

FIGS. 6A-6C are cross-sectional views illustrating a manufacturing step of the semiconductor laser device according to the embodiment. FIG. 6A is a cross-sectional view illustrating a manufacturing step taken along the line A-A′ (the non-current injection region) of FIG. 1. FIG. 6B is a cross-sectional view illustrating a manufacturing step taken along the line B-B′ (the current injection region) of FIG. 1. FIG. 6C is a cross-sectional view illustrating a manufacturing step taken along the line C-C′ (in the extending direction of the ridge) of FIG. 1.

FIGS. 7A-7C are cross-sectional views illustrating a manufacturing step of the semiconductor laser device according to the embodiment. FIG. 7A is a cross-sectional view illustrating a manufacturing step taken along the line A-A′ (the non-current injection region) of FIG. 1. FIG. 7B is a cross-sectional view illustrating a manufacturing step taken along the line B-B′ (the current injection region) of FIG. 1. FIG. 7C is a cross-sectional view illustrating a manufacturing step taken along the line C-C′ (in the extending direction of the ridge) of FIG. 1.

FIGS. 8A-8C are cross-sectional views illustrating a manufacturing step of the semiconductor laser device according to the embodiment. FIG. 8A is a cross-sectional view illustrating a manufacturing step taken along the line A-A′ (the non-current injection region) of FIG. 1. FIG. 8B is a cross-sectional view illustrating a manufacturing step taken along the line B-B′ (the current injection region) of FIG. 1. FIG. 8C is a cross-sectional view illustrating a manufacturing step taken along the line C-C′ (in the extending direction of the ridge) of FIG. 1.

FIGS. 9A-9C are cross-sectional views illustrating a manufacturing step of the semiconductor laser device according to the embodiment. FIG. 9A is a cross-sectional view illustrating a manufacturing step taken along the line A-A′ (the non-current injection region) of FIG. 1. FIG. 9B is a cross-sectional view illustrating a manufacturing step taken along the line B-B′ (the current injection region) of FIG. 1. FIG. 9C is a cross-sectional view illustrating a manufacturing step taken along the line C-C′ (in the extending direction of the ridge) of FIG. 1.

FIGS. 10A-10C are cross-sectional views illustrating a manufacturing step of the semiconductor laser device according to the embodiment. FIG. 10A is a cross-sectional view illustrating a manufacturing step taken along the line A-A′ (the non-current injection region) of FIG. 1. FIG. 10B is a cross-sectional view illustrating a manufacturing step taken along the line B-B′ (the current injection region) of FIG. 1. FIG. 10C is a cross-sectional view illustrating a manufacturing step taken along the line C-C′ (in the extending direction of the ridge) of FIG. 1.

FIGS. 11A-11C are cross-sectional views illustrating a manufacturing step of the semiconductor laser device according to the embodiment. FIG. 11A is a cross-sectional view illustrating a manufacturing step taken along the line A-A′ (the non-current injection region) of FIG. 1. FIG. 11B is a cross-sectional view illustrating a manufacturing step taken along the line B-B′ (the current injection region) of FIG. 1. FIG. 11C is a cross-sectional view illustrating a manufacturing step taken along the line C-C′ (in the extending direction of the ridge) of FIG. 1.

FIGS. 12A-12C are cross-sectional views illustrating a manufacturing step of the semiconductor laser device according to the embodiment. FIG. 12A is a cross-sectional view illustrating a manufacturing step taken along the line A-A′ (the non-current injection region) of FIG. 1. FIG. 12B is a cross-sectional view illustrating a manufacturing step taken along the line B-B′ (the current injection region) of FIG. 1. FIG. 12C is a cross-sectional view illustrating a manufacturing step taken along the line C-C′ (in the extending direction of the ridge) of FIG. 1.

FIGS. 13A-13C are cross-sectional views illustrating a manufacturing step of the semiconductor laser device according to the embodiment. FIG. 13A is a cross-sectional view illustrating a manufacturing step taken along the line A-A′ (the non-current injection region) of FIG. 1. FIG. 13B is a cross-sectional view illustrating a manufacturing step taken along the line B-B′ (the current injection region) of FIG. 1. FIG. 13C is a cross-sectional view illustrating a manufacturing step taken along the line C-C′ (in the extending direction of the ridge) of FIG. 1.

FIGS. 14A-14C are cross-sectional views illustrating a manufacturing step of the semiconductor laser device according to the embodiment. FIG. 14A is a cross-sectional view illustrating a manufacturing step taken along the line A-A′ (the non-current injection region) of FIG. 1. FIG. 14B is a cross-sectional view illustrating a manufacturing step taken along the line B-B′ (the current injection region) of FIG. 1. FIG. 14C is a cross-sectional view illustrating a manufacturing step taken along the line C-C′ (in the extending direction of the ridge) of FIG. 1.

FIGS. 15A-15C are cross-sectional views illustrating a manufacturing step of the semiconductor laser device according to the embodiment. FIG. 15A is a cross-sectional view illustrating a manufacturing step taken along the line A-A′ (the non-current injection region) of FIG. 1. FIG. 15B is a cross-sectional view illustrating a manufacturing step taken along the line B-B′ (the current injection region) of FIG. 1. FIG. 15C is a cross-sectional view illustrating a manufacturing step taken along the line C-C′ (in the extending direction of the ridge) of FIG. 1.

FIGS. 16A-16C are graphs illustrating a result of conducting electron spectroscopy for chemical analysis (ESCA) of the surface of a p⁺-type contact layer of the semiconductor laser device according to the embodiment. Specifically, FIG. 16A is a graph illustrating a chemical shift of N1s electrons. FIG. 16B is a graph illustrating a chemical shift of Ga3d electrons. FIG. 16C is a graph illustrating a chemical shift of O1s electrons.

FIG. 17A is a cross-sectional image of the semiconductor laser device according to the embodiment taken by a transmission electron microscope (TEM) near the interface between a p-electrode and the p⁺-type contact layer in the direction perpendicular to the extending direction of the ridge. FIG. 17B is a cross-sectional image of a semiconductor laser device according to the embodiment taken by a scanning electron microscope (SEM) near a non-current injection portion in the extending direction of the ridge.

FIG. 18A is a graph illustrating current-voltage characteristics of the semiconductor laser device according to the embodiment in comparison with a conventional example. FIG. 18B illustrates a schematic structure of the semiconductor laser device according to the embodiment. FIG. 18C illustrates a schematic structure of a semiconductor laser device in the conventional example, in which a pad electrode extends onto a dielectric film which serves as a non-current injection portion.

FIG. 19A is a graph illustrating a result of plotting SBH characteristics versus ideality factor n in the semiconductor laser device according to the embodiment in comparison with a conventional example. FIG. 19B illustrates a schematic structure of the semiconductor laser device according to the embodiment. FIG. 19C illustrates a schematic structure of the semiconductor laser device in a conventional example, in which a pad electrode extends onto a dielectric film which serves as a non-current injection portion.

FIG. 20 is a band diagram illustrating a mechanism of improving contact characteristics of the semiconductor laser device according to the embodiment.

FIG. 21A illustrates current-optical output power characteristics of the semiconductor laser device according to the embodiment in comparison with a conventional example. FIG. 21B illustrates a schematic structure of the semiconductor laser device according to the embodiment. FIG. 21C illustrates a schematic structure of the semiconductor laser device in a conventional example, in which a pad electrode extends onto a dielectric film which serves as a non-current injection portion.

FIG. 22A is a cross-sectional view taken in the width direction (the direction perpendicular to the extending direction of the ridge) in the central portion of a resonator of the semiconductor laser device according to the first conventional art shown in Japanese Patent Publication No. 2008-034587. FIG. 22B is a cross-sectional view taken in the width direction near resonator facets in the semiconductor laser device according to the first conventional art. FIG. 22C is a cross-sectional view taken in a length direction (i.e., the extending direction of the ridge) in the semiconductor laser device according to the first conventional art.

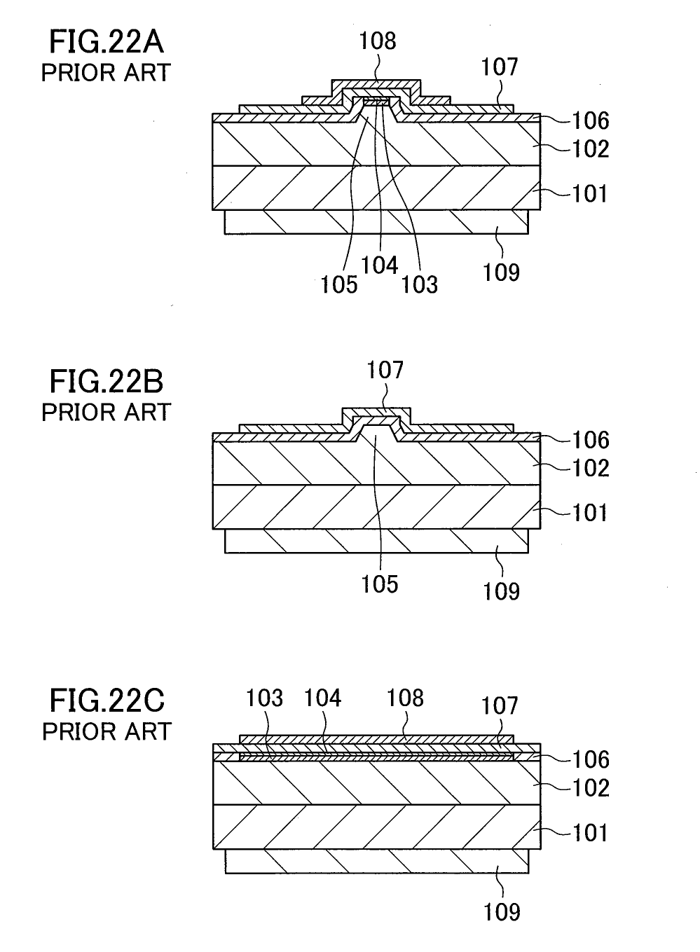

FIG. 23A is a cross-sectional view taken in the length direction near a resonator facet of the semiconductor laser device according to the second conventional art shown in Japanese Patent Publication No. 2008-227002. FIG. 23B is a bottom view near the resonator facet of the semiconductor laser device according to the second conventional art.

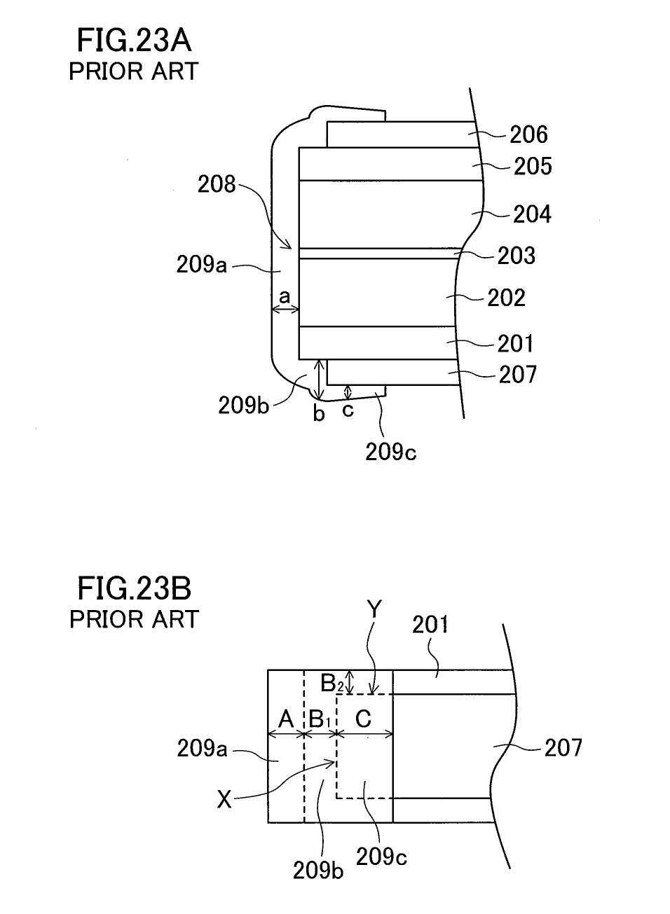

### DETAILED DESCRIPTION

Embodiment of a semiconductor laser device (semiconductor light-emitting device such as a GaN semiconductor laser diode) according to the present disclosure and a method of manufacturing the device will be described hereinafter in detail with reference to the drawings.

Note that the semiconductor laser device according to the present disclosure is applicable to various types of devices based on the following structure.

Specifically, in the semiconductor laser device according to the present disclosure, a light confining dielectric film of a ridge sidewall serving as a current confining layer, a dielectric film of a non-current injection region, and a p-electrode are formed by self-alignment; and the dielectric films and the p-electrode are symmetric. This reduces deviation of the center of the optical axis. Furthermore, the dielectric film of the non-current injection region and the dielectric film serving as the current confining layer are formed in a monolithic-integrated manner. The p-electrode (Schottky electrode) is formed at a desired position on a ridge portion. The desired position is adjacent to the non-current injection region. This structure reduces physicochemical influence on a contact layer surface during a wafer process, cleavage, or formation of a coating film.

A native oxide layer of semiconductor exists on the contact layer surface on the ridge portion. However, in the manufacturing method of the semiconductor laser device according to the present disclosure, manufacturing processes are performed so that a change of state of the native oxide layer on the contact layer surface of the non-current injection region covered by the dielectric film does not change the electronic state of the contact layer surface of the p-electrode formation region. Specifically, the second electrode provided in a region including the upper surface of the p-electrode and functioning as a pad electrode is spaced apart from the upper surface region of the dielectric film of the non-current injection region. This reduces influence of a change in the Fermi level at the connection interface between the dielectric film of the non-current injection region and e.g., the p⁺-type GaN contact layer on the Fermi level at the connection interface between the p-electrode and e.g., the p⁻-type GaN contact layer. Therefore, degradation of the contact characteristics between the p-electrode and the contact layer is reducible.

### Embodiment

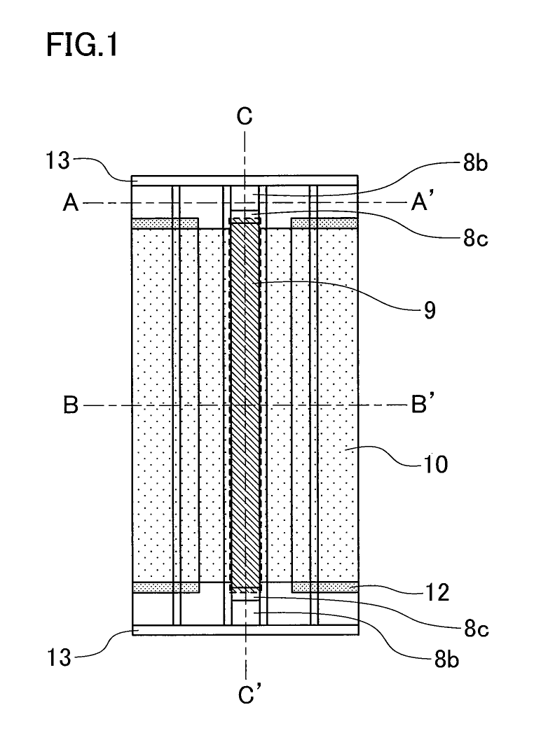

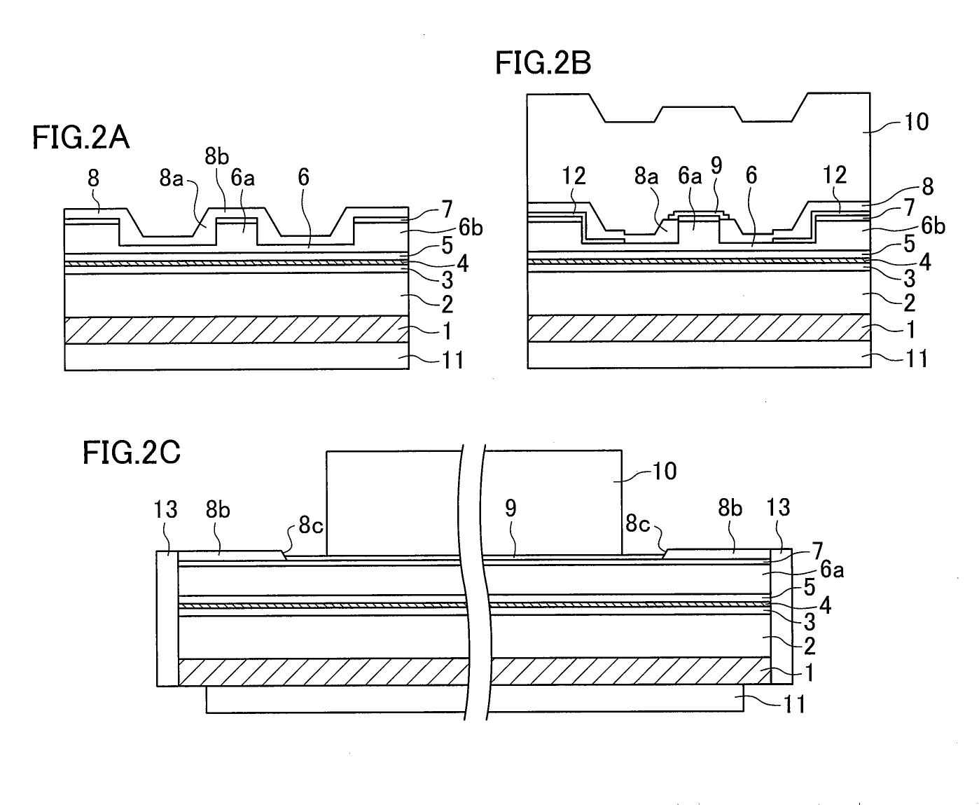

FIG. 1 is a top view illustrating the structure of a semiconductor laser device according to an embodiment, and specifically, a GaN semiconductor laser diode. FIG. 2A is a cross-sectional view taken along the line A-A′ (the non-current injection region) of FIG. 1. FIG. 2B is a cross-sectional view taken along the line B-B′ (the current injection region) of FIG. 1. FIG. 2C is a cross-sectional view taken along the line C-C′ (in the extending direction of the ridge) of FIG. 1.

As shown in FIG. 1 and FIGS. 2A-2C, an n-type cladding layer 2 having e.g., a thickness of about 2.5 μm and made of n-type AlₓGa₁₋ₓN (where x=0.03) is formed on an n-type GaN substrate 1. An n-type optical guide layer 3 having e.g., a thickness of about 0.1 μm and made of n-type GaN is formed on the n-type cladding layer 2. A multiple quantum well active layer 4 including a barrier layer having e.g., a thickness of about 8 nm and made of In_{z}Ga_{1-z}N (where z=0.08), and a well layer having e.g., a thickness of about 3 nm and made of InₛGa₁₋ₛN (where s=0.03) is formed on the n-type optical guide layer 3. A p-type optical guide layer 5 having, e.g., a thickness of about 0.1 μm and made of p-type GaN is formed on the multiple quantum well active layer 4. A p-type cladding layer 6 made of e.g., p-type AlₜGa₁₋ₜN (where t=0.03) is formed on the p-type optical guide layer 5. The p-type cladding layer 6 includes a ridge portion 6a in a stripe shape with a thickness of e.g., about 0.5 μm, which extends between both facets of a resonator (both facets of the laser), and a wing portion 6b having the same degree of step portion as the ridge portion 6a.

While the wing portion 6b has the structure for mechanically protecting the ridge portion 6a, the wing portion 6b may not be formed.

A p⁺-type contact layer 7 having e.g., a thickness of about 60 nm and made of p⁺-type GaN is formed on the upper surfaces of the ridge portion 6a and the wing portion 6b. A native oxide layer containing Ga, N, and O and having a thickness of less than 1 nm exists on the surface of the p⁺-type contact layer 7. In the following description, the “ridge portion 6a” includes the p⁺-type contact layer 7.

In a current injection region (see FIG. 2B), an absorption layer 12 covering the region from the p⁺-type contact layer 7 on the wing portion 6b to a point short of reaching the ridge portion 6a. While the absorption layer 12 contributes to absorption of stray light, the absorption layer 12 may not be provided.

A dielectric film 8 is formed to cover both side surfaces of the ridge portion 6a of the current injection region, both side surfaces and the upper surface of the ridge portion 6a of the non-current injection region, both side surfaces and the upper surface of the wing portion 6b, and the region between the ridge portion 6a and the wing portion 6b. The dielectric film 8 has an opening for injecting current into the upper surface of the ridge portion 6a. Furthermore, the dielectric film 8 includes a current confining layer 8a formed on both side surfaces of the ridge portion 6a, and a non-current injection portion 8b formed on the upper surface of the ridge portion 6a of the non-current injection region. That is, the current confining layer 8a and the non-current injection portion 8b are formed in a monolithic-integrated manner.

A p-electrode 9 which is a thin film of high work function metal such as Pd, Pt, and Ni, and connected to the p⁺-type contact layer 7 is formed on the surface of the p⁺-type contact layer 7 exposed to the opening of the dielectric film 8. The P-electrode 9 covers the upper surface of the p⁺-type contact layer 7 exposed from the current confining layer 8a, and does not exist on the side surfaces of the ridge portion 6a. Also, the p-electrode 9 does not exist on the dielectric film 8 except for the upper surface of the current confining layer 8a near the side surfaces of the ridge portion 6a. Note that the P-electrode 9 may be in contact with the sidewall surfaces 8c of the non-current injection portion 8b.

A pad electrode 10 is formed on the p-electrode 9. The pad electrode 10 is spaced apart from the non-current injection portion 8b. Note that, in the region other than the region near the resonator facets, in which the p⁺-type contact layer 7 is in contact with the dielectric film 8 (the non-current injection portion 8b), the pad electrode 10 may extend on a side of the ridge portion 6a to be in contact with the dielectric film 8. As the pad electrode 10, a thin film having a desired multilayer structure capable of reducing metal interdiffusion, for example, a multilayer structure of Ti/Pt/Au and the like. When the pad electrode 10 is formed thick, for example, by using a plated film for a part of the multilayer structure of the pad electrode 10; the lower part of the multilayer structure may be spaced apart from the non-current injection portion 8b, and the upper part of the multilayer structure may be formed by electroplating using a thin film (not shown) connected to the lower part in the wafer surface as an electroplating seed film. This makes the removal process of the electroplating seed film unnecessary, which is required when forming the electroplating seed film over the entire surface of the wafer, thereby simplifying the manufacturing method.

The back surface (the surface opposite to the formation surface of the n-type cladding layer 2 etc.) of the n-type GaN substrate 1 is polished so that the n-type GaN substrate 1 has a desired thickness. An n-electrode 11 connected to the n-type GaN substrate 1 is formed on the back surface. A coating layer 13, which is a thin film having a desired structure, is formed on laser facets (both facets at the front and rear sides) formed by the cleavage process of the wafer.

Some of the features of this embodiment are that the non-current injection region, in which the p⁺-type contact layer 7 is in contact with the dielectric film 8 (the non-current injection portion 8b) on the upper surface of the ridge portion 6a near the resonator facets, is provided, and that the pad electrode 10 is spaced apart from the upper surface region of the non-current injection portion 8b of the non-current injection region.

According to this embodiment, the pad electrode 10 which is electrically conductive with (i.e., having the same potential as) the p-electrode 9 is not provided on the dielectric film 8 serving as the non-current injection portion 8b near the resonator facets. Thus, characteristics of the connection interface between the p-electrode 9 and the p⁺-type contact layer 7 are not affected by the Fermi level determined by the native oxide layer formed on the crystal surface of the p⁺-type contact layer 7 under the non-current injection portion 8b which is continuous with the crystal surface of the p⁺-type contact layer 7 under the p-electrode 9. Thus, since the contact resistance between the p-electrode 9 and the p⁺-type contact layer 7 can be reduced, a semiconductor laser device achieving high output power, long life, and a low operation voltage can be provided.

According to this embodiment, the n-type cladding layer 2, the multiple quantum well active layer 4, the p-type cladding layer 6, the p⁺-type contact layer 7, and the like are made of group III-V nitride compound semiconductor represented by InₓAl_{y}Ga_{1-x-y} N (where 0≦x≦1, 0≦y≦1, and x+y≦1). Thus, the oscillation wavelength of the semiconductor laser device may range from blue violet to green.

In this embodiment, at least a part of the p-electrode 9, which is in contact with the p⁺-type contact layer 7, is preferably made of a single metal or plural metals selected from the group consisting of Pd, Pt, and Ni. This enables formation of a p-electrode, which can be connected with low contact resistance to the p⁺-type GaN contact layer made of e.g., group III-V nitride compound semiconductor with a wide bandgap.

In this embodiment, the dielectric film 8 is preferably a silicon oxide film. This stabilizes the voltage of the laser to improve the COD level, and improves the linearity of current-optical output power (IL) characteristics, thereby mitigating an increase in the operating current according to an increase in the threshold current to enable high-output power operation. Therefore, a semiconductor laser device, which can stably monitor and control optical output power when used in e.g., an optical disk, can be provided.

In this embodiment, the distance between an end of the p-electrode 9 and one of the resonator facets (laser facets) preferably ranges from 1 μm to 10 μm. This stabilizes the voltage of the laser to improve the COD level, and improves the linearity of IL characteristics, thereby mitigating an increase in the operating current according to an increase in the threshold current to enable high-output power operation. Therefore, a semiconductor laser device, which can stably monitor and control optical output power when used in e.g., an optical disk, can be provided.

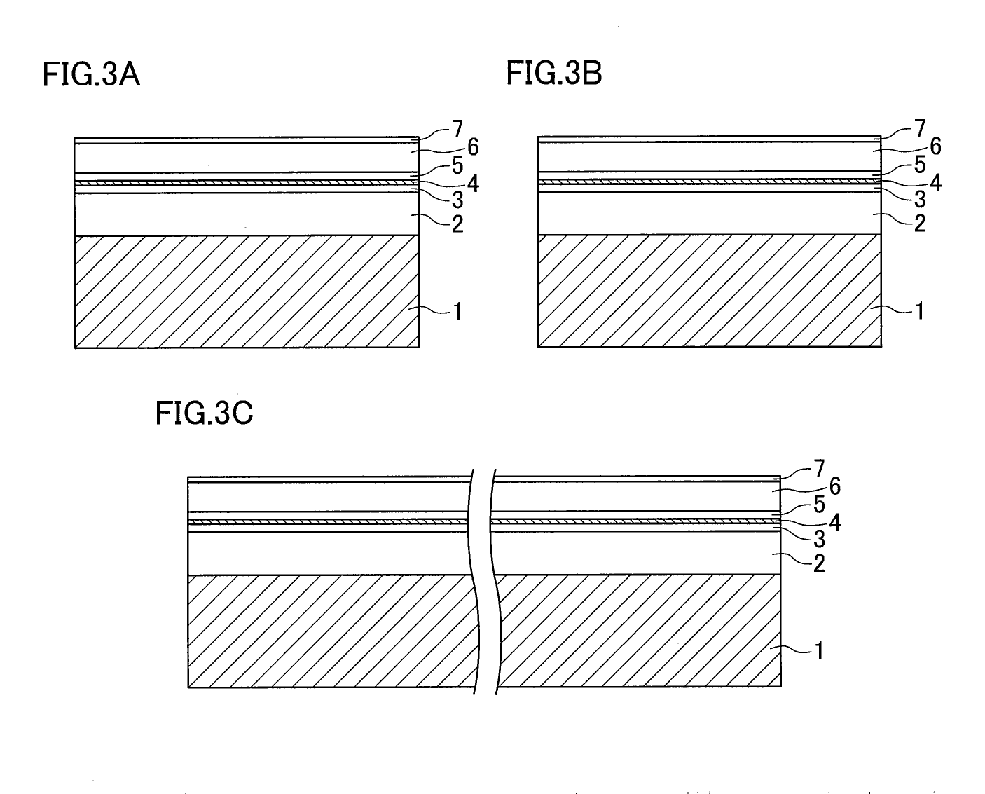

FIGS. 3A-3C, 4A-4C, 5A-5C, 6A-6C, 7A-7C, 8A-8C, 9A-9C, 10A-10C, 11A-11C, 12A-12C, 13A-13C, 14A-14C, and 15A-15C are cross-sectional views illustrating manufacturing steps of the semiconductor laser device according to the embodiment, specifically, a GaN semiconductor laser diode. Note that FIGS. 3A, 4A, 5A, 6A, 7A, 8A, 9A, 10A, 11A, 12A, 13A, 14A and 15A are cross-sectional views illustrating manufacturing steps taken along the line A-A′ (the non-current injection region) of FIG. 1. FIGS. 3B, 4B, 5B, 6B, 7B, 8B, 9B, 10B, 11B, 12B, 13B, 14B and 15B are cross-sectional views illustrating manufacturing steps taken along the line B-B′ (the current injection region) of FIG. 1. FIGS. 3C, 4C, 5C, 6C, 7C, 8C, 9C, 10C, 11C, 12C, 13C, 14C and 15C are cross-sectional views illustrating manufacturing steps taken along the line C-C′ (the extending direction of the ridge) of FIG. 1.

First, as shown in FIGS. 3A-3C, a semiconductor multilayer is formed on the n-type GaN substrate 1. Specifically, the n-type cladding layer 2, the n-type optical guide layer 3, the multiple quantum well active layer 4, the p-type optical guide layer 5, the p-type cladding layer 6, and the p⁺-type contact layer 7 are formed from the bottom on the n-type GaN substrate 1, by for example, metal organic chemical vapor deposition (MOCVD). The materials for the metal organic chemical vapor deposition, trimethylgallium can be used for Ga, trimethylaluminum can be used for Al, trimethylindium can be used for In, and ammonia can be used for N. Cyclopentadienyl magnesium can be used for Mg as p-type dopant, and Si can be used as n-type dopant. Nitrogen and hydrogen can be used as carrier gas in the metal organic chemical vapor deposition.

Note that the present disclosure is not limited to the above-described semiconductor layers and the manufacturing method, and is clearly applicable even if another growing method of the semiconductor layers and another structures of the semiconductor layers are used.

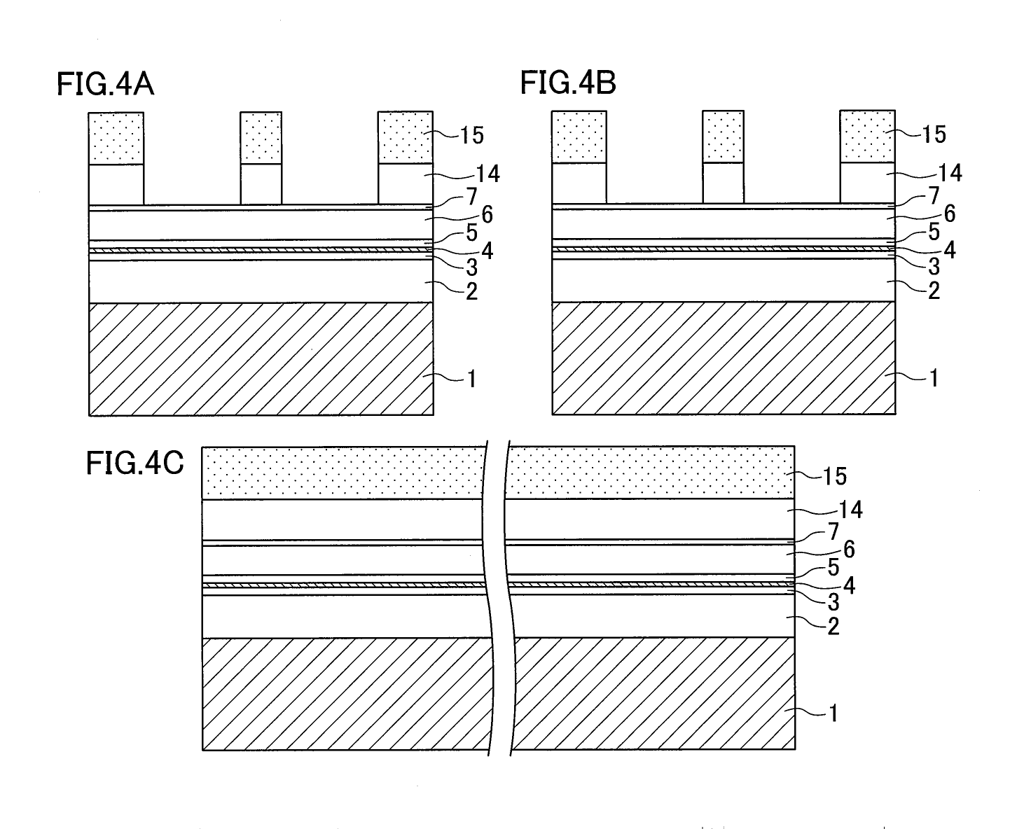

Next, as shown in FIGS. 4A-4C, a mask pattern 14 having a desired thickness and made of SiO₂ is formed on the p⁺-type contact layer 7 by dry etching or wet etching with a resist pattern 15.

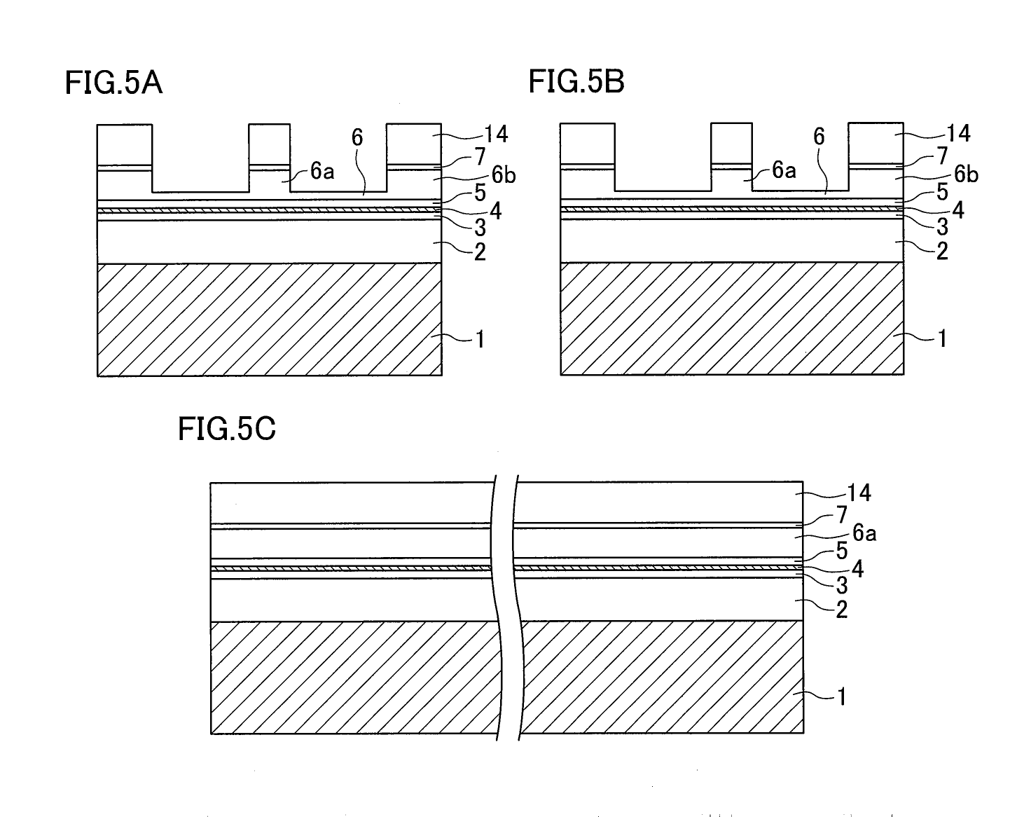

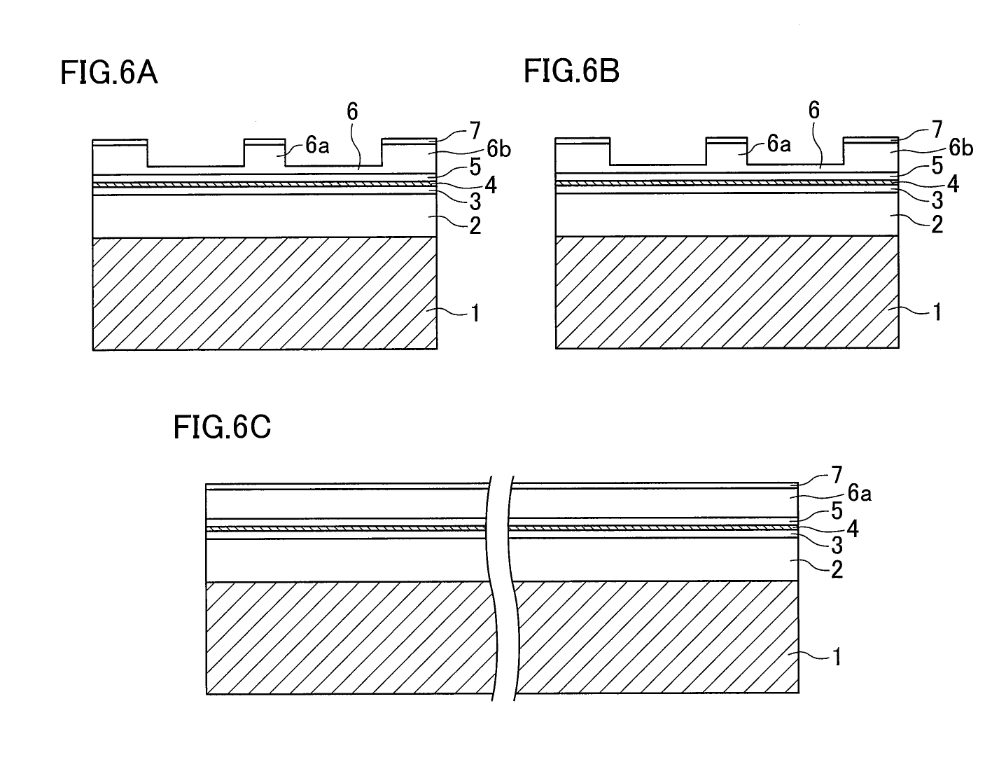

Then, as shown in FIGS. 5A-5C, using the mask pattern 14 as a mask, a part of the p-type cladding layer 6 and the p⁺-type contact layer 7 in a predetermined region is removed by etching such as dry etching with e.g., chlorine gas (Cl₂). After that, as shown in FIGS. 6A-6C, the mask pattern 14 is removed by wet etching with e.g., buffered hydrofluoric acid (BHF). As a result, the ridge portion 6a and the wing portion 6b having the same degree of step structure as the ridge portion 6a is formed. While the wing portion 6b has the structure mechanically protecting the ridge portion 6a, the wing portion 6b may not be provided. Note that the thickness of the p-type cladding layer 6 before etching is e.g., about 0.5 μm.

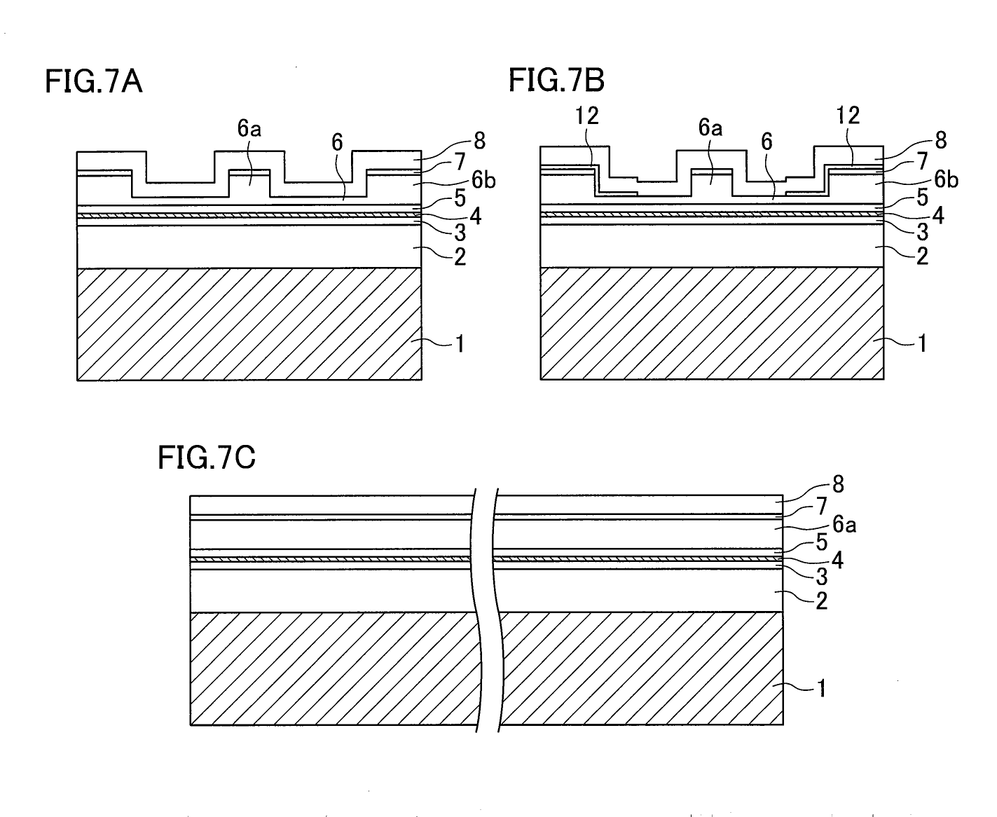

After cleaning with the above buffered hydrofluoric acid (BHF), as shown in FIGS. 7A-7C, the dielectric film 8 made of e.g., SiO₂ is formed by e.g., chemical vapor deposition (CVD) to cover the entire surface of the substrate including the ridge portion 6a and the wing portion 6b. The CVD for forming the dielectric film 8 is not limited to thermal CVD, plasma CVD, and the like, as long as it does not cause a physicochemical change in the constituent element and the thickness in the native oxide layer which exists on the surface of the p⁺-type contact layer 7. The thickness of the dielectric film 8 may range from about 50 nm to 1000 nm. The thickness may range from about 50 nm to 300 nm, when considering the optical confinement effect by the dielectric film 8 and influence of stress of the dielectric film 8 on the semiconductor layer.

In this embodiment, the dielectric film 8 is formed in two steps. The absorption layer 12 contributing to absorption of laser stray light is formed to cover the region from the p⁺-type contact layer 7 on the wing portion 6b to a point short of reaching the ridge portion 6a by the formation of the dielectric film 8 and spacer liftoff.

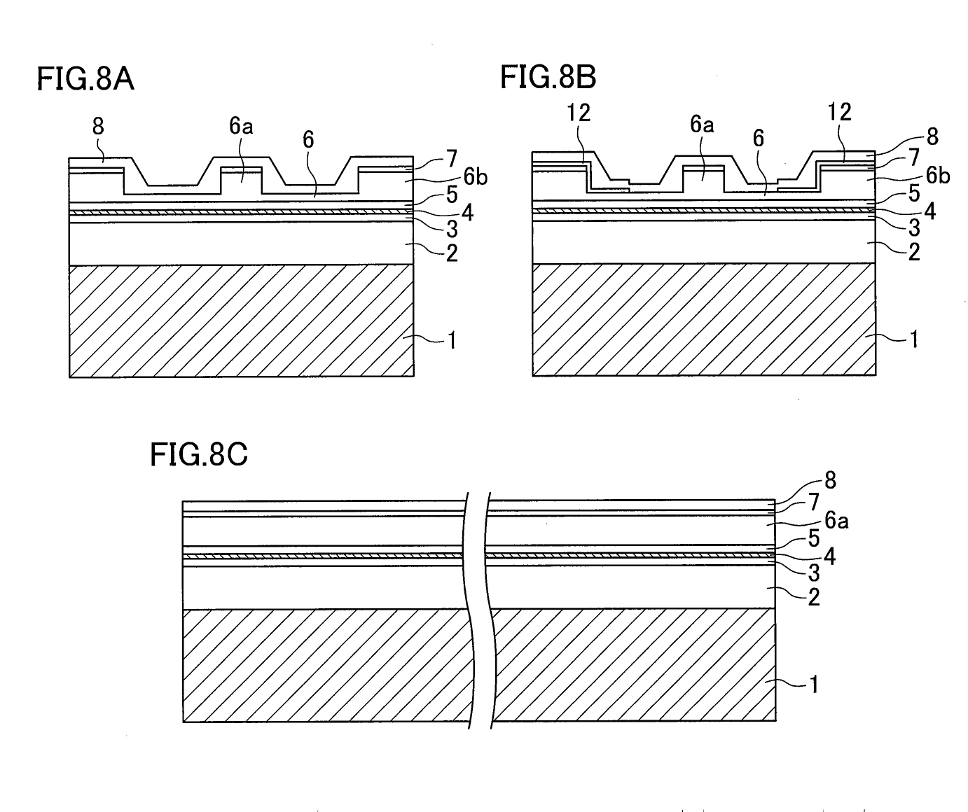

Then, as shown in FIGS. 8A-8C, the dielectric film 8 is shaped by reactive ion etching (ME), which is one type of dry etching, using inert gas such as Ar gas. Due to the etching, the step coverage of the dielectric film 8 deposited on the side surfaces of the ridge portion 6a and the wing portion 6b is changed from a perpendicular shape to a normal mesa shape having a desired tilt angle ranging from about 85° to about 70°. As such, the dielectric film 8 is shaped into a normal mesa regardless of the shapes of the ridge portion 6a and the wing portion 6b so that the pad electrode 10 can be formed smoothly even at the step portion. This prevents device destruction due to electric field concentration starting from a part in which the pad electrode 10 becomes discontinuous due to the step portion.

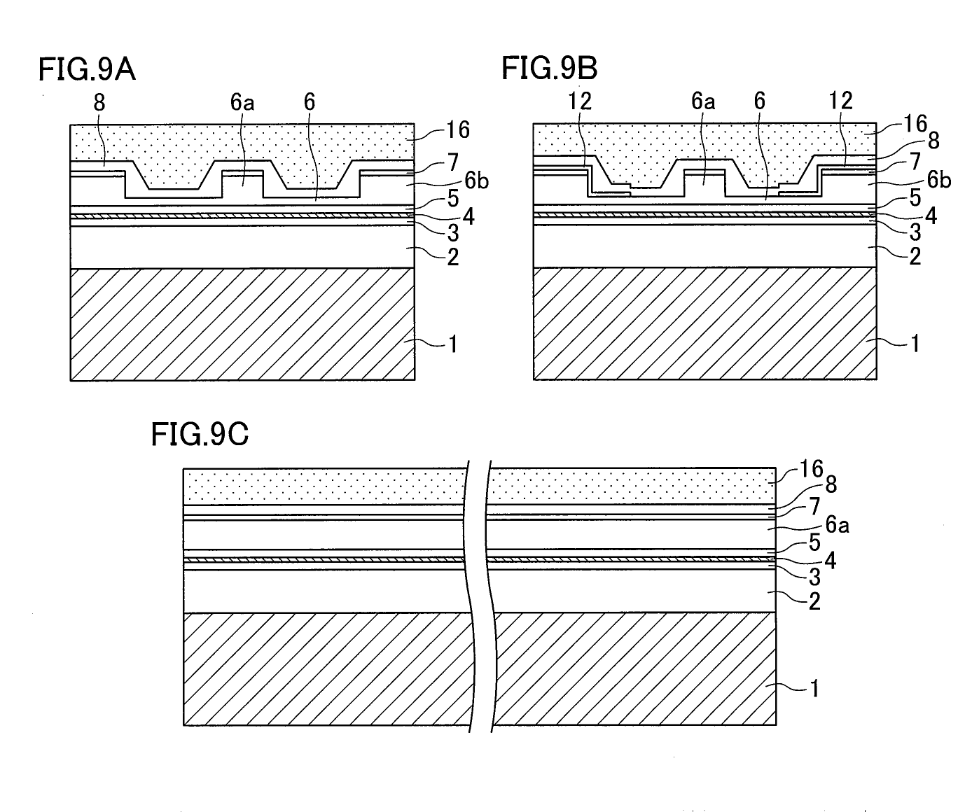

Next, as shown in FIGS. 9A-9C, a first resist film 16 is applied over the entire surface of the dielectric film 8 with a desired thickness so that the first resist film 16 may achieve required flatness near the ridge portion 6a. Then, the first resist film 16 is deactivated by heat treatment at the temperature of 150° C. or more e.g., heat treatment at the temperature of about 170° C. for about 20 minutes. While the method of deactivating the resist is not limited, deactivation such as UV curing may be used.

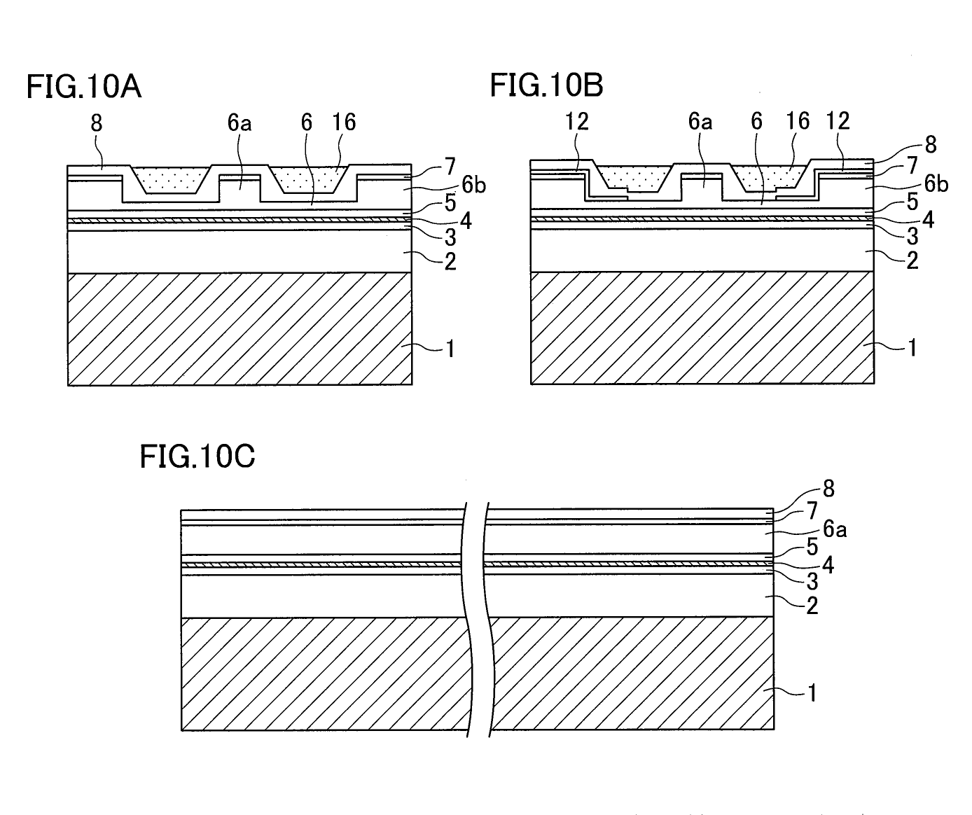

After that, as shown in FIGS. 10A-10C, the first resist film 16 is etched back by for example, oxygen plasma treatment to expose a vertex of the dielectric film 8 on the ridge portion 6a.

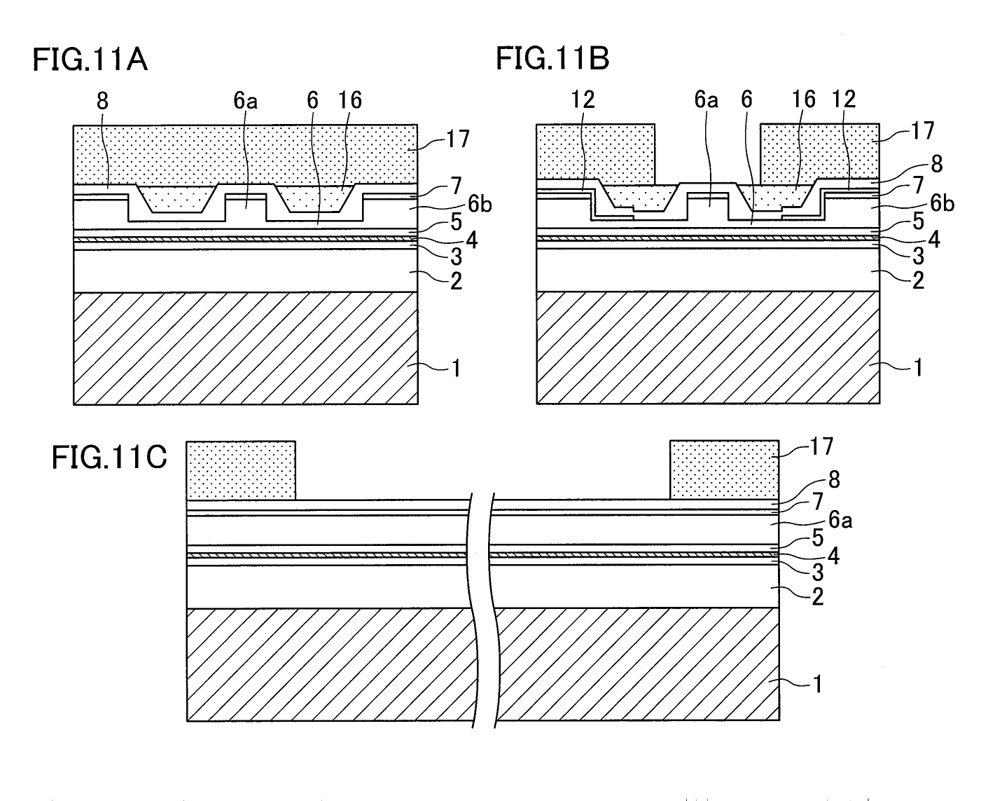

Next, as shown in FIGS. 11A-11C, a second resist film 17 for forming a p-electrode is applied over the entire surface of the substrate including the top of the first resist film 16 after the etch back. Then, the opening is patterned by lithography in a desired region serving as the p-electrode formation region in the second resist film 17. As shown in FIGS. 11A-11C, the non-current injection region can be easily formed by using the remaining second resist film 17 as a mask pattern.

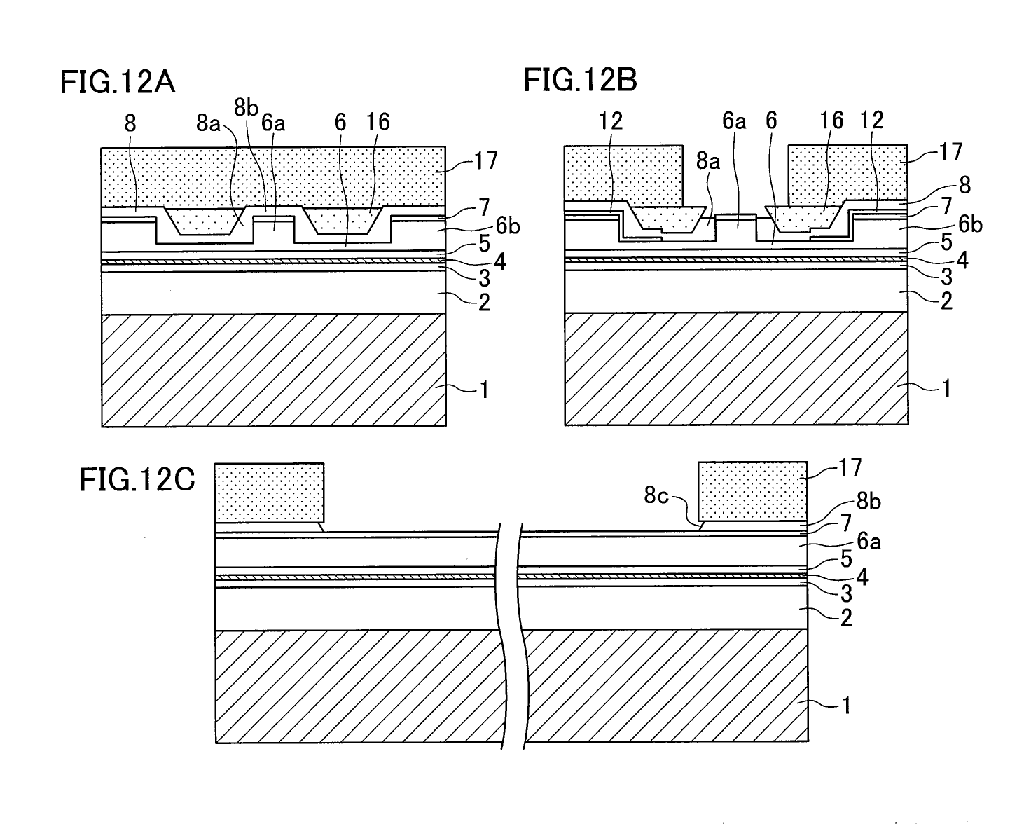

Next, as shown in FIGS. 12A-12C, a desired part of the dielectric film 8 is removed on the ridge portion 6a by wet etching with buffered hydrofluoric acid (BHF) using the remaining first resist film 16 and the remaining second resist film 17 as a mask. As a result, as shown in FIGS. 12A-12C, an opening for forming the p-electrode 9 is formed on the p⁺-type contact layer 7, and the current confining layer 8a is formed with the same height and shape on the right and left sides of the ridge portion 6a in the opening. Furthermore, using the second resist film 17 covering a desired region of the ridge portion 6a as a mask pattern, the non-current injection portion 8b having the same shape as the mask pattern is formed in a monolithic-integrated manner with the current confining layer 8a.

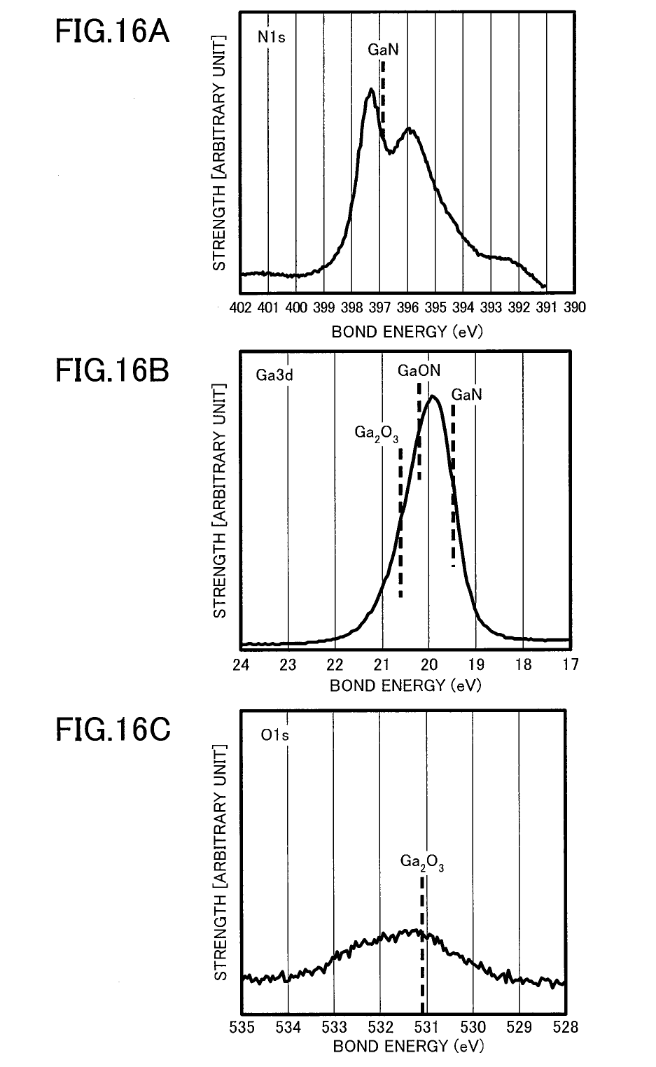

FIGS. 16A-16C are graphs illustrating a result of conducting electron spectroscopy for chemical analysis (ESCA) of the surface of a p⁺-type contact layer 7. Specifically, FIG. 16A illustrates a chemical shift of N1s electrons. FIG. 16B illustrates a chemical shift of Ga3d electrons. FIG. 16C illustrates a chemical shift of O1s electrons.

As shown in FIGS. 16A-16C, the native oxide layer containing Ga, N and O with a thickness larger than about 0 nm and less than 1 nm exists on the surface of the p⁺-type contact layer 7 which is cleaned by the buffered hydrofluoric acid (BHF). As such, the native oxide layer growing in a self-controlled manner has a surface state in the bandgap of the p⁺-type contact layer 7.

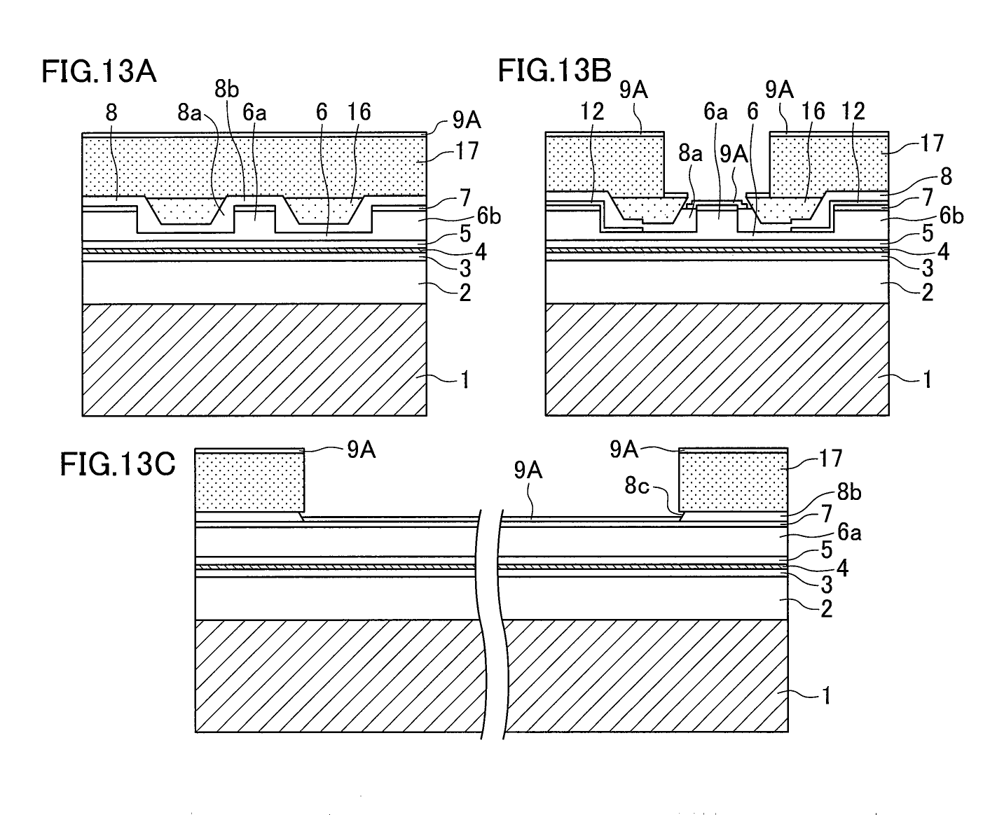

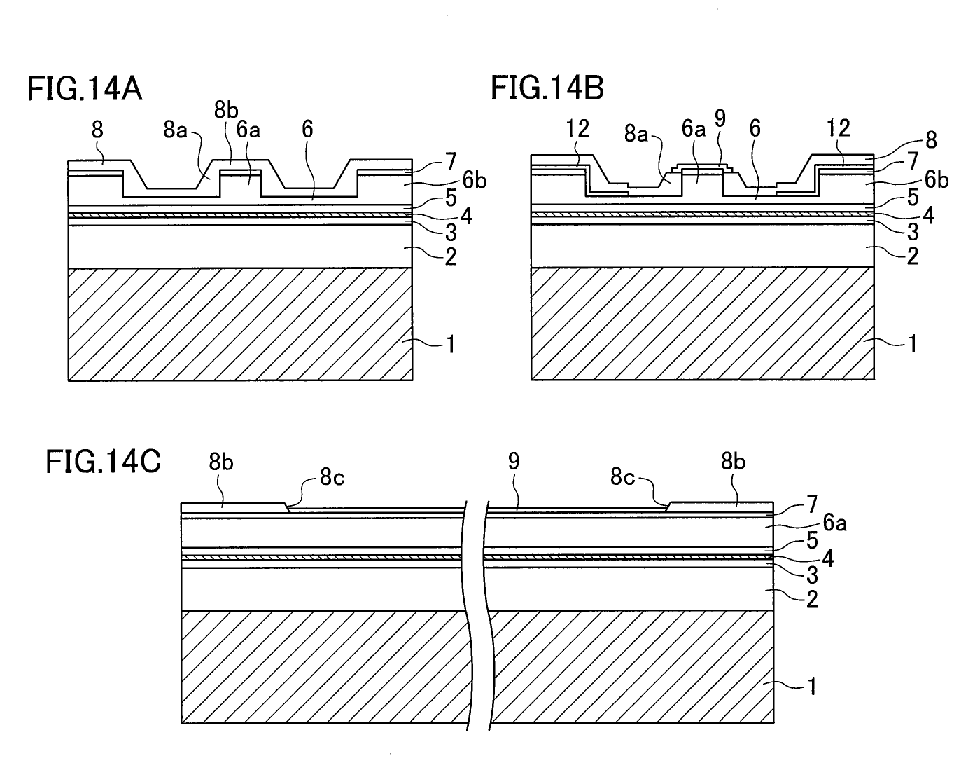

Next, as shown in FIGS. 13A-13C, a thin film 9A to be the p-electrode 9 is deposited over the entire surface of the substrate. Then, as shown in FIGS. 14A-14C, the unnecessary thin film 9A formed on the first resist film 16 and the second resist film 17 is removed by lifting off the first resist film 16 and the second resist film 17. As a result, the p-electrode 9 formed on the p⁺-type contact layer 7 can be obtained. The liftoff may be performed with cleaning agent containing a nitrogen compound such as cleaning agent containing pyrrolidone, which does not corrode the p-electrode 9. As the p-electrode 9, high work function metal, which can be connected with low contact resistance to a p⁺-type GaN contact layer made of e.g., group III-V nitride compound semiconductor with a wide bandgap, may be formed with a desired thickness. Specifically, the p-electrode 9 may be a thin film made of a single metal or plural metals selected from the group consisting of e.g., Pd, Pt, and Ni.

By the above-described process, the current confining layer 8a located on the side of the ridge portion 6a and made of SiO₂ (the dielectric film 8) and the p-electrode 9 are symmetrically formed. Also, the non-current injection portion 8b located on the ridge portion 6a near the resonator facets and made of SiO₂ (the dielectric film 8) and the p-electrode 9 are formed in a self-aligned manner. This stabilizes the voltage of the laser to improve the COD level, and improves linearity of current-optical output power (IL) characteristics, thereby mitigating an increase in the operating current according to an increase in the threshold current to enable high-output power operation.

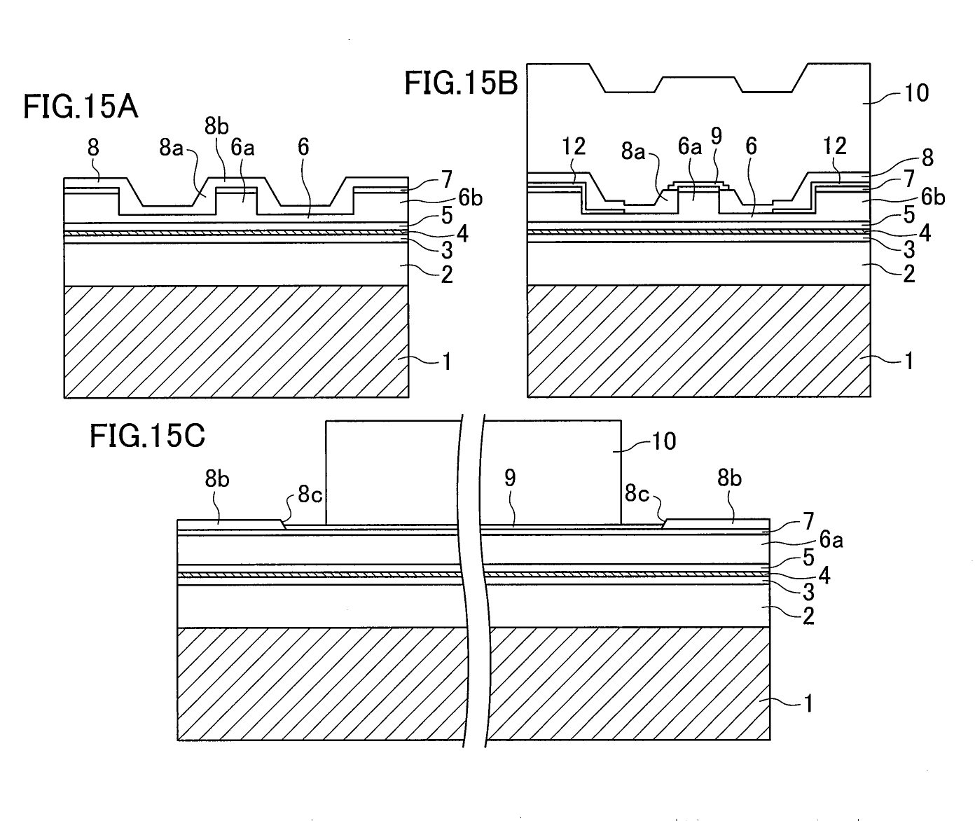

Next, as shown in FIGS. 15A-15C, the pad electrode 10 is formed on the p-electrode 9. The pad electrode 10 may be a thin film having a multilayer structure such as Ti/Pt/Au capable of reducing metal interdiffusion. When the pad electrode 10 is formed by deposition and lift-off, cleaning agent containing a nitrogen compound such as pyrrolidone, which does not corrode the pad electrode 10 may be used. As one of the features of this embodiment, as shown in FIG. 15C, the pad electrode 10 is spaced apart from the upper surface region of the non-current injection portion 8b, thereby avoiding the problem that the pad electrode 10 serves as a metal thin film electrically conductive with the p-electrode 9 on the non-current injection portion 8b. This reduces influence of a change in the Fermi level at the interface between the non-current injection portion 8b and the p⁺-type contact layer 7 on the Fermi level at the interface between the p-electrode 9 and the p⁺-type contact layer 7 through the native oxide layer, which is continuous from the non-current injection region to the current injection region on the surface of the p⁺-type contact layer 7. Therefore, contact characteristics can be improved.

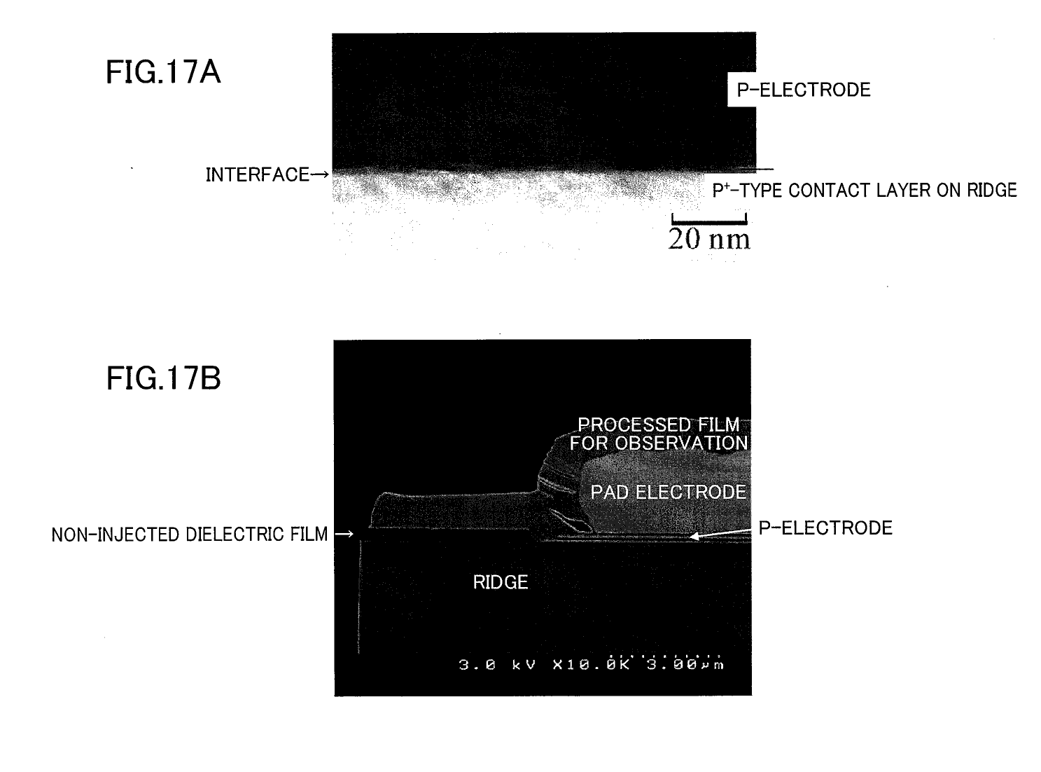

FIG. 17A is a cross-sectional image taken by a transmission electron microscope (TEM) near the interface between the p-electrode 9 and the p⁺-type contact layer 7 in the direction perpendicular to the extending direction of the ridge. FIG. 17B is a cross-sectional image taken by a scanning electron microscope (SEM) near the non-current injection portion 8b in the extending direction of the ridge.

As shown in FIG. 17A, the interface between the p-electrode 9 and the p⁺-type contact layer 7 forms a Schottky-connected metal/semiconductor interface, but does not from an eutectic alloy. Also, as shown in FIG. 17B, the interface between the p-electrode 9 and the p⁺-type contact layer 7 has the interface phase in which the eutectic alloy is not formed to the vicinity of the non-current injection portion 8b. While the p-electrode 9 is spaced apart from the upper surface of the dielectric film serving as the non-current injection portion 8b, the p-electrode 9 may not be spaced apart from the sidewall of the non-current injection portion 8b. Also, the pad electrode 10 is formed on the upper surface of the p-electrode 9 to be spaced apart from the dielectric film which serves as the non-current injection portion 8b.

When the pad electrode 10 is formed thick, for example, by using a plated film for a part of the multilayer structure of the pad electrode 10, the lower part of the multilayer structure may be spaced apart from the non-current injection portion 8b, and the upper part of the multilayer structure may be formed by electroplating, using a thin film connected to the lower part in the wafer surface as an electroplating seed film (not shown). Then, the pad electrode 10 is formed thick (e.g., a thickness of 1 μm or more). This makes the removal process of the electroplating seed film, which is required when forming the electroplating seed film over the entire surface of the wafer, thereby simplifying the manufacturing method.

Next, the back surface (the surface opposite to the formation surface of the n-type cladding layer 2 etc.) of the n-type GaN substrate 1 is polished so that the n-type GaN substrate 1 has a desired thickness. Then, the n electrode 11 connected to the n-type GaN substrate 1 is formed on the back surface. After the cleavage process of the wafer, the coating layer 13 which is a thin film having a desired structure is formed on laser facets (both facets at the front and rear sides) formed by the cleavage. As a result, the structure of the semiconductor laser device according to the embodiments shown in FIG. 1 and FIGS. 2A-2C, specifically, a GaN semiconductor laser diode can be obtained.

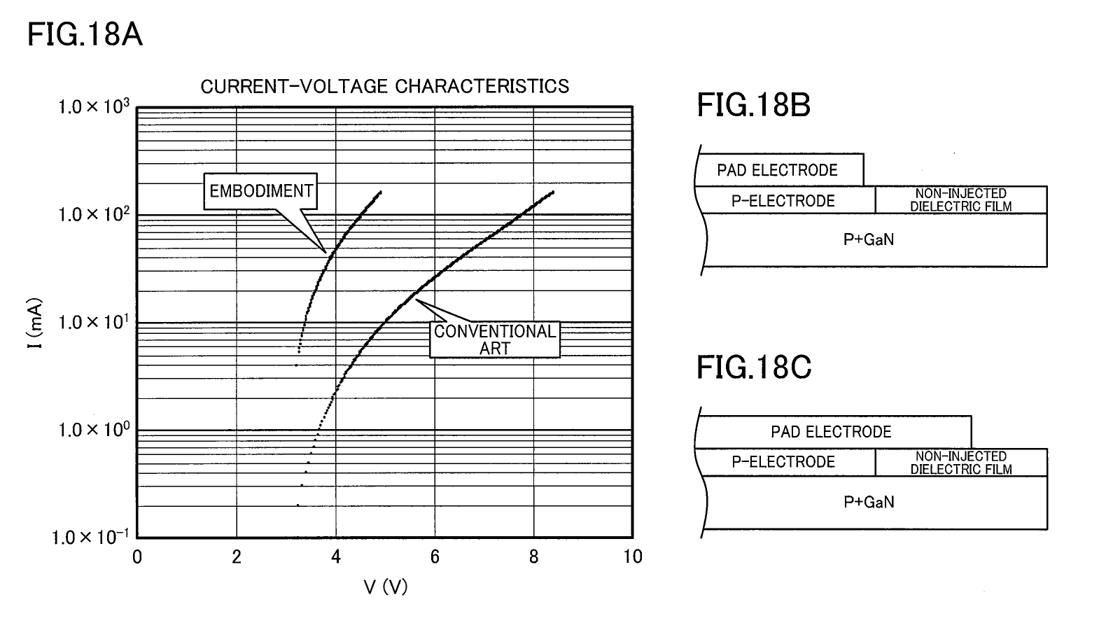

FIG. 18A illustrates current-voltage characteristics of the semiconductor laser device in this embodiment, in which the pad electrode is spaced apart from the upper surface of the dielectric film serving as the non-current injection portion (see FIG. 18B) in comparison with the conventional example in which the pad electrode extends onto the dielectric film serving as the non-current injection portion (see FIG. 18C).

As shown in FIG. 18A, while the current of about 46 mA can be obtained at the voltage of 4.0 V in this embodiment, the current of only about 2.2 mA can be obtained at the voltage of 4.0 V in the conventional example. As such, according to the current-voltage characteristics of this embodiment, large current can be obtained at the same voltage in comparison with the conventional example, thereby achieving lower contact resistance.

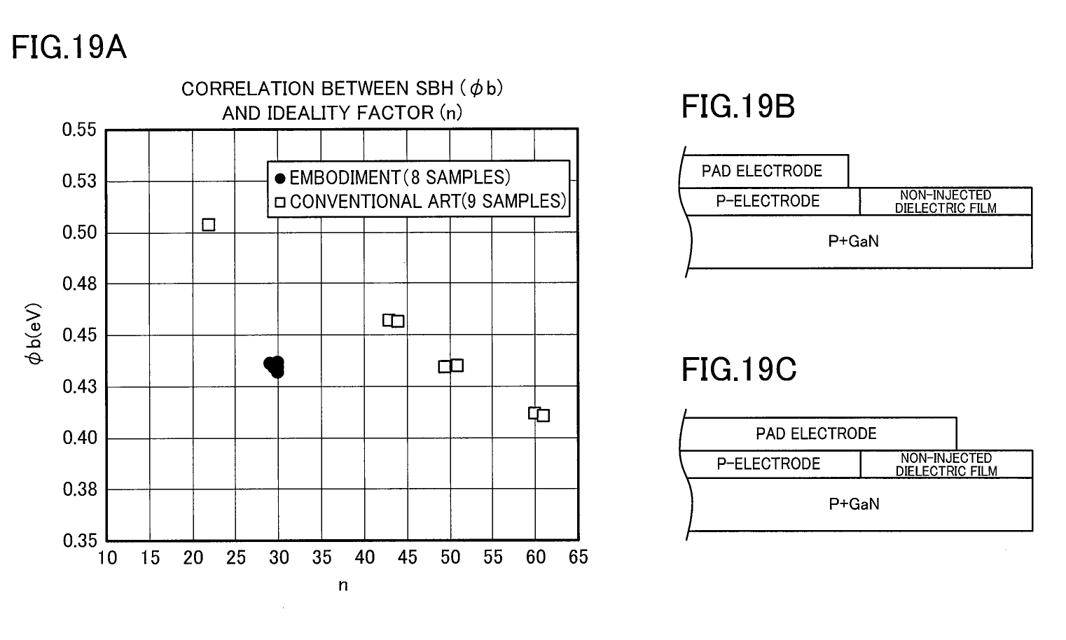

FIG. 19A illustrates a result of plotting Schottky barrier height (SBH) characteristics versus ideality factor n in the semiconductor laser device of this embodiment in which the pad electrode is spaced apart from the upper surface of the dielectric film serving as the non-current injection portion (see FIG. 19B) in comparison with the conventional example in which the pad electrode extends onto the dielectric film serving as the non-current injection portion (see FIG. 19C).

As shown in FIG. 19A, φb is concentrated at about 0.44 eV, and the value n is concentrated at about 30 in this embodiment. On the other hand, φb is distributed in a range from about 0.42 eV to 0.51 eV and the value n is continuously distributed in a range from about 21 to 60 with a certain tendency in the conventional example.

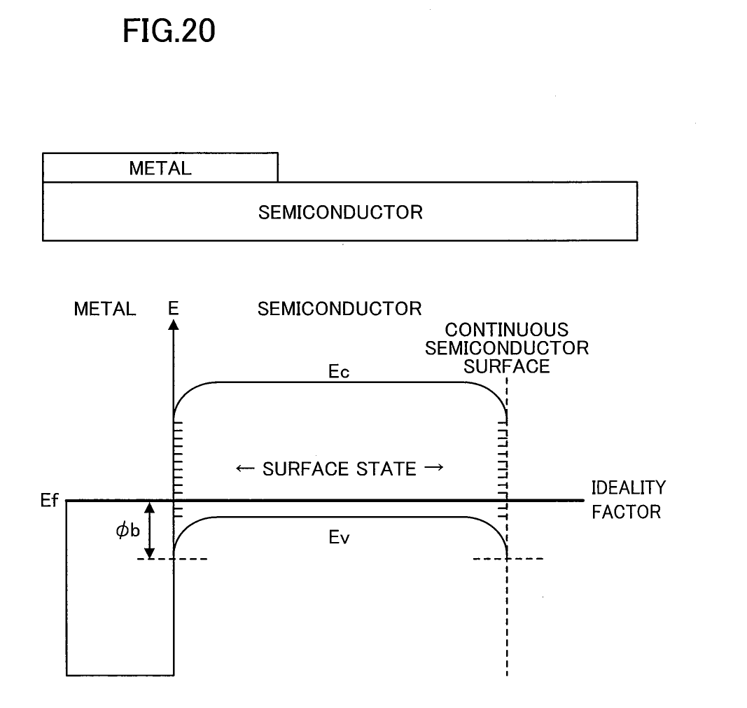

FIG. 20 is a band diagram illustrating a mechanism that differences in the distribution of φb and the value n caused by the differences in the structures of the non-current injection regions occur.

As shown in FIG. 20, the surface states (Tamm states), which are obtained by quantizing the semiconductor surface native oxides continuous from the current injection region to the non-current injection region, define the Fermi level of the metal/semiconductor interface. This uniquely defines φb and value n of the metal/semiconductor interface including the semiconductor surface of the non-current injection region continuous with the metal/semiconductor interface. Therefore, as in this embodiment, using a process which does not change the state of the native oxide layer on the surface of the p⁺-type GaN contact layer made of GaN semiconductor, and designing the structure in which an electrode and a dielectric film are arranged not to affect the Fermi level at the metal (electrode)/semiconductor interface, which is continuous with the semiconductor surface of the non-current injection region, are important to stabilize the contact characteristics.

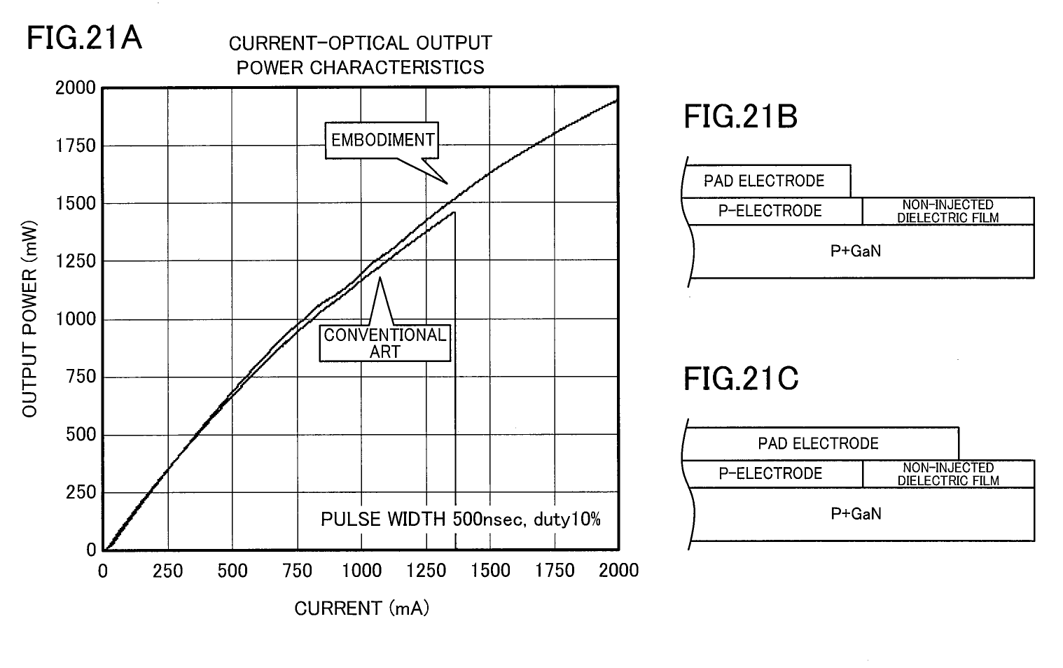

FIG. 21A illustrates current-optical output power characteristics before life test of the semiconductor laser device (specifically, a GaN semiconductor laser diode) in this embodiment in which the pad electrode is spaced apart from the upper surface of the dielectric film serving as the non-current injection portion (see FIG. 21B) in comparison with the conventional example in which the pad electrode extends onto the dielectric film serving as the non-current injection portion (see FIG. 21C).

As shown in FIG. 21A, under the condition where the pulse width is 500 nsec and the pulse duty ratio is 10%, CODs occur near the facet of the p-electrode where the current exceeds about 1300 mA in the GaN semiconductor laser diode in the conventional example. On the other hand, in the GaN semiconductor laser diode in this embodiment, current-optical output power characteristics in which no damage occurs until the current reaches 2000 mA. As such, high output power characteristics are achieved in this embodiment. Specifically, as in this embodiment, the structure design, which stabilizes the Fermi level at the Schottky contact interface by reducing changes in the native oxide state existing on the continuous surface of the p+-type GaN contact layer including the interface between the p+-type GaN and the non-current injection portion formed of the dielectric film near the resonator facet, is important for high output power operation in GaN semiconductor lasers.

What is claimed is:

1. A semiconductor laser device comprising:
a substrate;
a first conductivity type semiconductor layer, an active layer, a second conductivity type semiconductor layer, and a second conductivity type contact layer, which are sequentially stacked on the substrate;
a ridge portion provided in the second conductivity type semiconductor layer and the second conductivity type contact layer, and extending between both facets of a resonator;
a current confining layer being in contact with the ridge portion, and having an opening on an upper surface of the ridge portion;
a first electrode provided in the opening to be in contact with the second conductivity type contact layer; and
a second electrode provided on the first electrode, wherein
a non-current injection portion is provided on the upper surface of the ridge portion near the resonator facets to be in contact with the second conductivity type contact layer,
the current confining layer and the non-current injection portion are formed of a same dielectric film, and
the second electrode is spaced apart from an upper surface region of the non-current injection portion.

2. The semiconductor laser device of claim 1, wherein
the first electrode is in contact with a sidewall surface of the non-current injection portion.

3. The semiconductor laser device of claim 1, wherein
the second electrode extends to a side of the ridge portion to be in contact with the dielectric film in a region other than regions near the resonator facets provided with the non-current injection portion.

4. The semiconductor laser device of claim 1, wherein
a native oxide layer is formed on a surface of a part of the second conductivity type contact layer which is in contact with the first electrode.

5. The semiconductor laser device of claim 4, wherein
the native oxide layer contains elements constituting the second conductivity type contact layer and oxygen, and
the native oxide layer has a thickness larger than 0 nm and less than 1 nm.

6. The semiconductor laser device of claim 1, wherein
a semiconductor multilayer including the first conductivity type semiconductor layer, the active layer, the second conductivity type semiconductor layer, and the second conductivity type contact layer is made of group III-V nitride compound semiconductor represented by InₓAl_{y}Ga_{1-x-y}N (where 0≦x≦1, 0≦y≦1, and x+y≦1).

7. The semiconductor laser device of claim 1, wherein
a part of the first electrode being in contact with the upper surface of the second conductivity type contact layer is made of a single metal or plural metals selected from the group consisting of Pd, Pt, and Ni.

8. The semiconductor laser device of claim 1, wherein
the dielectric film is a silicon oxide film.

9. The semiconductor laser device of claim 1, wherein
a distance between an end of the first electrode and one of the resonator facets ranges from 1 μm to 10 μm.

10. A manufacturing method of a semiconductor laser device comprising the steps of:
(a) forming a semiconductor multilayer, in which a first conductivity type semiconductor layer, an active layer, a second conductivity type semiconductor layer, and a second conductivity type contact layer are sequentially stacked on a substrate;
(b) forming a ridge portion extending between both facets of a resonator by etching the second conductivity type semiconductor layer and the second conductivity type contact layer;
(c) forming a dielectric film on the semiconductor multilayer;
(d) after applying first resist onto the dielectric film, deactivating the first resist;
(e) exposing a part of the dielectric film located on the ridge portion by etching back the first resist;
(f) after applying second resist onto the first resist, performing exposure and development of the second resist, thereby forming an opening in an electrode formation region on the ridge portion;
(g) removing a part of the dielectric film located in the electrode formation region by etching using the first resist and the second resist as a mask to expose the upper surface of the ridge portion in the electrode formation region;
(h) forming a first electrode film on the exposed portion of the upper surface of the ridge portion, the first resist and the second resist; and
(i) lifting off the first resist and the second resist to remove the first electrode film formed on the first resist and the second resist, thereby forming a first electrode on the upper surface of the ridge portion.

11. The method of claim 10, wherein
before the step (d), a part of the dielectric film is etched by dry etching with inert gas.

12. The method of claim 11, wherein
the inert gas is argon.

13. The method of claim 10, wherein
in the step (g), wet etching is used for etching the dielectric film.

14. The method of claim 13, wherein
in the step (g), solution containing hydrofluoric acid is used for etching the dielectric film.

15. The method of claim 10, wherein
in the step (i), the first resist and the second resist are lifted off with cleaning agent containing a nitrogen compound.

16. The method of claim 15, wherein
the cleaning agent containing the nitrogen compound is cleaning agent containing pyrrolidone.

17. The method of claim 10, further comprising
after the step (i), the step (j) forming a second electrode on the first electrode.

18. The method of claim 17, wherein
the second electrode includes a plurality of metal layers, and
at least one of the plurality of metal layers is formed by plating.

19. The method of claim 18, wherein
the at least one metal layer formed by the plating has a thickness of 1 μm or more.

20. The method of claim 10, wherein
the semiconductor multilayer is made of group III-V nitride compound semiconductor represented by InₓAl_{y}Ga_{1-x-y}N (where 0≦x≦1, 0≦y≦1, and x+y≦1).
